(19) United States
(12) Patent Application Publication
(10) Pub. No.: US 2025/0299735 A1
(43) Pub. Date: Sep. 25, 2025

(54) SEMICONDUCTOR DEVICE AND STORAGE MEDIUM

(71) Applicant: Kioxia Corporation, Tokyo (JP)

(72) Inventors: Toshiyuki ENDA, Yokohama (JP); Tooru MARUYAMA, Kamakura (JP); Kohei OIKAWA, Yokohama (JP); Kojiro SUZUKI, Kawasaki (JP); Takashi MAEDA, Kamakura (JP)

(73) Assignee: Kioxia Corporation, Tokyo (JP)

(21) Appl. No.: 19/075,067

(22) Filed: Mar. 10, 2025

(30) Foreign Application Priority Data
Mar. 21, 2024 (JP) 2024-045420

(51) Int. Cl. G11C 16/04; G11C 5/06; G11C 16/10; G11C 16/26

(52) U.S. Cl. CPC G11C 16/0483; G11C 5/063; G11C 16/10; G11C 16/26

(57) ABSTRACT

According to one embodiment, a semiconductor device includes a first bit line, strings, and a first control circuit. The strings are coupled to the first bit line. Each string includes a select transistor and memory cells, which are coupled in series. The first control circuit is configured to execute a logical operation. In the logical operation, the first control circuit is configured to execute a read operation to apply a first voltage to the select transistors of at least two strings of the strings, to apply a second voltage lower than the first voltage to the select transistor of a string other than the at least two strings, to apply a third voltage to at least two memory cells of the memory cells of each string, and to apply a fourth voltage higher than the third voltage to the memory cells other than the at least two memory cells.

### CROSS-REFERENCE TO RELATED APPLICATION

This application is based upon and claims the benefit of priority from prior Japanese Patent Application No. 2024-045420, filed Mar. 21, 2024, the entire contents of which are incorporated herein by reference.

### FIELD

Embodiments described herein relate generally to a semiconductor device and a storage medium.

### BACKGROUND

A NAND flash memory capable of storing data in a nonvolatile manner is known.

### BRIEF DESCRIPTION OF THE DRAWINGS

FIG. 1 is a block diagram illustrating an example of a configuration of an information processing system according to a first embodiment.

FIG. 2 is a block diagram illustrating an example of a configuration of a semiconductor device according to the first embodiment.

FIG. 3 is a block diagram illustrating an example of a configuration of an information processor included in the semiconductor device according to the first embodiment.

FIG. 4 is a circuit diagram illustrating an example of a circuit configuration of a memory cell array included in the semiconductor device according to the first embodiment.

FIG. 5 is a flowchart illustrating an example of information processing of the semiconductor device according to the first embodiment.

FIG. 6 is a schematic diagram illustrating an example of a read operation of the semiconductor device according to the first embodiment.

FIG. 7 is a block diagram illustrating an example of a configuration of an information processor included in a semiconductor device according to a second embodiment.

FIG. 8 is a flowchart illustrating an example of information processing of the semiconductor device according to the second embodiment.

FIG. 9 is a block diagram illustrating an example of a configuration of a semiconductor device according to a third embodiment.

FIG. 10 is a flowchart illustrating an example of information processing of the semiconductor device according to the third embodiment.

FIG. 11 is a schematic diagram illustrating an example of threshold voltage distribution of memory cell transistors included in a semiconductor device according to a fourth embodiment.

FIG. 12 is a schematic diagram illustrating a specific example of a storage process of the semiconductor device according to the fourth embodiment.

FIG. 13 is a schematic diagram illustrating a specific example of the storage process of the semiconductor device according to the fourth embodiment.

FIG. 14 is a schematic diagram illustrating a specific example of the storage process of the semiconductor device according to the fourth embodiment.

FIG. 15 is a schematic diagram illustrating a specific example of a comparison process of the semiconductor device according to the fourth embodiment.

FIG. 16 is a schematic diagram illustrating a specific example of the comparison process of the semiconductor device according to the fourth embodiment.

FIG. 17 is a schematic diagram illustrating a specific example of an addition process of the semiconductor device according to the fourth embodiment.

FIG. 18 is a schematic diagram illustrating a specific example of the addition process of the semiconductor device according to the fourth embodiment.

FIG. 19 is a schematic diagram illustrating a specific example of the addition process of the semiconductor device according to the fourth embodiment.

FIG. 20 is a schematic diagram illustrating an example of a method of arranging data in memory cells included in the semiconductor device according to the fourth embodiment.

FIG. 21 is a schematic diagram illustrating a specific example of an exclusive OR (XOR) process of the semiconductor device according to the fourth embodiment.

FIG. 22 is a schematic diagram illustrating a specific example of the exclusive OR (XOR) process of the semiconductor device according to the fourth embodiment.

FIG. 23 is a schematic diagram illustrating a specific example of the exclusive OR (XOR) process of the semiconductor device according to the fourth embodiment.

FIG. 24 is a schematic diagram illustrating an example of parallel processing of the exclusive OR (XOR) process of the semiconductor device according to the fourth embodiment.

FIG. 25 is a schematic diagram illustrating a specific example of an exclusive NOR (XNOR) process of the semiconductor device according to the fourth embodiment.

### DETAILED DESCRIPTION

In general, according to one embodiment, a semiconductor device includes a first bit line, strings, and a first control circuit. The plurality of strings coupled to the first bit line. Each of the strings includes a select transistor and a plurality memory cells. The select transistor and the memory cells are coupled in series. The first control circuit is configured to execute a logical operation. In the logical operation, the first control circuit is configured to execute a read operation to apply a first voltage to the select transistors of at least two strings of the strings, to apply a second voltage lower than the first voltage to the select transistor of a string other than the at least two strings, to apply a third voltage to at least two memory cells of the memory cells of each of the strings, and to apply a fourth voltage higher than the third voltage to the memory cells other than the at least two memory cells.

Hereinafter, embodiments will be described with reference to the drawings. The embodiments will exemplify apparatuses and methods for embodying the technical idea of the invention. The drawings are schematic or conceptual. In the present specification, components having substantially the same function and configuration are marked with the same reference signs. The numerals, characters, etc. added to reference signs are referred to by the same reference signs, and are used to distinguish between similar elements.

### <1> First Embodiment

A first embodiment relates to an information processing system 1 that executes a logical operation using a memory device. Hereinafter, the information processing system 1 according to the first embodiment is described.

### <1-1> Configuration

To begin with, a configuration of the information processing system 1 according to the first embodiment is described.

### <1-1-1> Configuration of Information Processing System 1

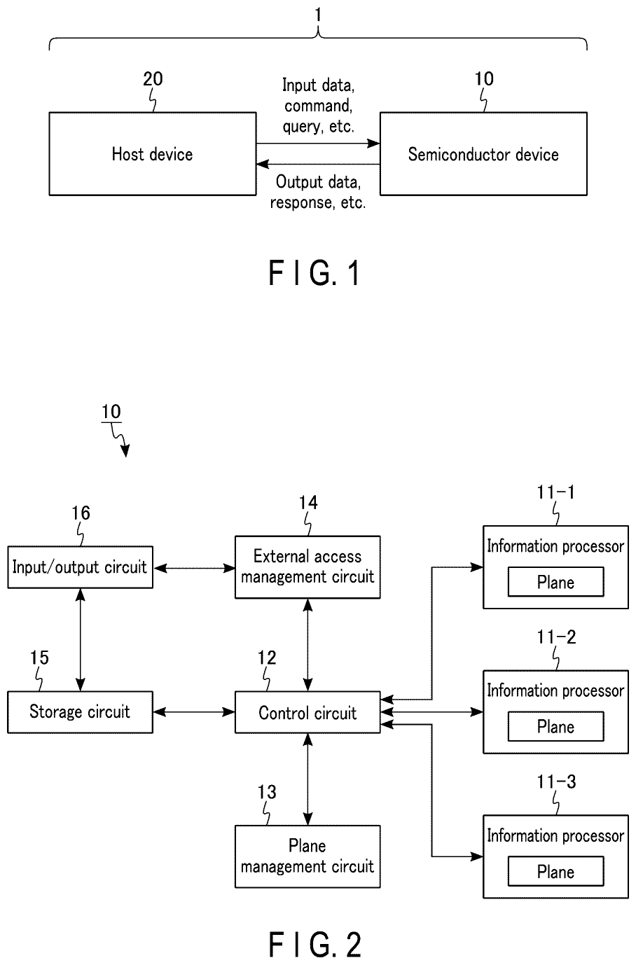

FIG. 1 is a block diagram illustrating an example of a configuration of the information processing system 1 according to the first embodiment. As illustrated in FIG. 1, the information processing system 1 includes, for example, a semiconductor device 10 and a host device 20. The semiconductor device 10 operates, based on an instruction of the host device 20. The host device 20 is, for example, an information terminal such as a personal computer (PC). The semiconductor device 10 and the host device 20 are configured to be mutually communicable. For example, the host device 20 transmits input data, a command, a query, and the like to the semiconductor device 10. The semiconductor device 10 transmits output data, a response to a query, and the like to the host device 20. The semiconductor device 10 is a memory device including a function of executing a logical operation. The semiconductor device 10 includes, for example, a similar configuration to a NAND flash memory including three-dimensionally stacked memory cells. The semiconductor device 10 can store input data received from the host device 20, into an internal storage area. In addition, the semiconductor device 10 can execute an operation based on a command, a query or the like received from the host device 20. In a case where the semiconductor device 10 receives a query from the host device 20, the semiconductor device 10 can execute information processing corresponding to the query by using the storage area, and can transmit a result of the information processing as a response to the host device 20.

### <1-1-2> Configuration of Semiconductor Device 10

FIG. 2 is a block diagram illustrating an example of the configuration of the semiconductor device 10 according to the first embodiment. As illustrated in FIG. 2, the semiconductor device 10 includes, for example, a plurality of information processors 11 (11-1, 11-2 and 11-3), a control circuit 12, a plane management circuit 13, an external access management circuit 14, a storage circuit 15, and an input/output circuit 16.

The information processor 11 includes a plane corresponding to a circuit that can store data. The plane is composed of, for example, a memory cell array including a set of memory cells, and interconnects and peripheral circuits for controlling the memory cell array. In addition, the information processor 11 is configured to be capable of executing a logical operation by a read operation on the plane. Note that a function of a specific logical operation may be assigned to each of the information processors 11 included in the semiconductor device 10. Hereinafter, a case is described in which the semiconductor device 10 includes three information processors 11-1, 11-2 and 11-3.

The control circuit 12 controls the overall operation of the semiconductor device 10. Specifically, the control circuit 12 controls the external access management circuit 14 in accordance with the operation state of each information processor 11, and restricts the access by the host device 20 to the semiconductor device 10. The control circuit 12 can transfer data between the storage circuit 15 and each information processor 11. Data that is transferred from the storage circuit 15 to the information processor 11 is input data received from the host device 20, data used in logical operations, and the like. Data that is transferred from the information processor 11 to the storage circuit 15 is output data read from the plane of the information processor, a result of a logical operation, and the like. The control circuit 12 can generate instructions for a read operation, a write operation and an erase operation, based on commands and address information stored in the storage circuit 15 and plane information acquired from the plane management circuit 13, and can transmit the generated instruction to any one of the information processors 11.

The plane management circuit 13 manages the planes of the respective information processors 11. The plane management circuit 13 collects information relating to the plane of each information processor 11. The plane management circuit 13 stores the collected information as plane information in an internal storage circuit. The plane information is accessed by the control circuit 12, and is utilized as configuration data relating to a logical operation. For example, based on the plane information, the control circuit 12 selects memory cells to be used for a logical operation, by selecting a word line WL, a select gate line SGD and a bit line BL to which such memory cells are coupled. Such selection of memory cells is determined by software such as a linker, by using configuration data.

The external access management circuit 14 manages the access of the host device 20 to the semiconductor device 10. The external access management circuit 14 controls the transmission/reception of data or the like using the input/output circuit 16 between the semiconductor device 10 and the host device 20, for example, based on a control signal that is input from the host device 20. In addition, the external access management circuit 14 includes an external access flag. The external access flag stores “1” in a case where an instruction relating to a logical operation is accepted, or in a case where a result of a logical operation can be output, and stores “0” in a case where an instruction relating to a logical operation is not accepted. The value of the external access flag can be changed by the control circuit 12. Note that the external access flag may be provided for each of the information processors 11.

The storage circuit 15 temporarily stores information that is used for the operation of the semiconductor device 10. The storage circuit 15 includes, for example, a register circuit or a cache memory. For example, the storage circuit 15 temporarily stores input data, a command, a query, and address information. The input data is, for example, data used for a logical operation by the semiconductor device 10, or data stored in a database. The command includes various instructions relating to various operations of the semiconductor device 10. The query is an instruction sentence relating to a logical operation that is to be executed by the information processor 11. The address information includes a block address, a page address, and a column address.

The input/output circuit 16 is an interface circuit that controls transmission/reception of signals such as data between the semiconductor device 10 and the host device 20. For example, based on the control of the external access management circuit 14, the input/output circuit 16 transmits the input data, command and query received from the host device 20 to the storage circuit 15, and transmits the output data, response and the like received from the storage circuit 15 to the host device 20. Note that the input/output circuit 16 may directly transmit and receive the data, query and response to and from each information processor 11.

### <1-1-3> Configuration of Information Processor 11

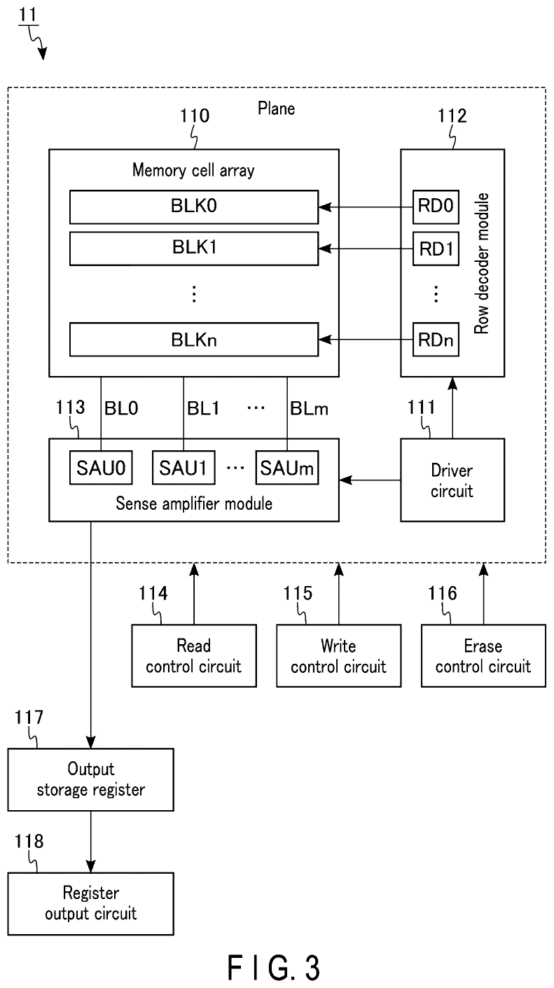

FIG. 3 is a block diagram illustrating an example of a configuration of the information processor 11 included in the semiconductor device 10 according to the first embodiment. As illustrated in FIG. 3, the information processor 11 includes, for example, a memory cell array 110, a driver circuit 111, a row decoder module 112, a sense amplifier module 113, a read control circuit 114, a write control circuit 115, an erase control circuit 116, an output storage register 117, and a register output circuit 118. The plane corresponds to, for example, a set of the memory cell array 110, driver circuit 111, row decoder module 112 and sense amplifier module 113. Note that it suffices that the plane includes at least the memory cell array 110.

The memory cell array 110 includes a plurality of blocks BLK0 to BLKn (“n” is an integer of 1 or more). The block BLK is a set of a plurality of memory cells. The block BLK corresponds to, for example, a unit of data erase. The block BLK includes a plurality of pages. The page corresponds to a unit by which data read and data write are executed. Although illustration is omitted, the memory cell array 110 is provided with a plurality of bit lines BL0 to BLm (“m” is an integer of 1 or more), a plurality of word lines WL, and a plurality of select gate lines SGD. Each memory cell is associated with, for example, one bit line BL and one word line WL. Each block BLK is associated with at least one select gate line SGD.

The driver circuit 111 generates voltage used in a read operation, a write operation, an erase operation, or the like. Then, the driver circuit 111 supplies the generated voltage to the row decoder module 112, the sense amplifier module 113, or the like.

The row decoder module 112 is a circuit used to select a block BLK that is an operation target, and to transfer voltage to interconnects such as a select gate line SGD, a word line WL and a select gate line SGS. The row decoder module 112 includes a plurality of row decoders RDO to RDn. The row decoders RDO to RDn are associated with the blocks BLK0 to BLKn, respectively, and are used to select the block BLK. Each row decoder RD transfers voltage generated by the driver circuit 111 to various interconnects provided in the memory cell array 110.

The sense amplifier module 113 is a circuit used to transfer voltage to each bit line BL, and to read data. The sense amplifier module 113 includes a plurality of sense amplifier units SAUO to SAUm. The sense amplifier units SAUO to SAUm are associated with the bit lines BL0 to BLm, respectively. Each sense amplifier unit SAU includes a sense amplifier capable of determining data, based on the voltage of the associated bit line BL, a latch circuit that temporarily stores data, and the like.

The read control circuit 114 executes a read operation, based on an instruction for a read operation (hereinafter referred to “read instruction”) that is received from the control circuit 12. A read instruction corresponding to a logical operation is configured to be capable of individually controlling voltages that are applied to all word lines WL and all select gate lines SGD, which are at least targets of the read operation. In the read operation corresponding to the logical operation, the voltages applied to the word lines WL are set at the same value for each layer in the blocks BLK. Specifically, the read instruction includes data of voltages, the number of which corresponds to the number of select gate lines SGD included in the memory cell array 110, and data of voltages, the number of which corresponds to the number of layers of the word lines WL. In addition, in a case of executing control as to whether or not to execute a read operation for each sense amplifier unit SAU, the read instruction for the logical operation includes an instruction to execute control as to whether or not to execute a read operation for each sense amplifier unit SAU. If the read control circuit 114 executes, based on a clock input from the control circuit, a read operation that is based on the read instruction, a read result is output to the sense amplifier module 113.

The write control circuit 115 controls the plane, based on an instruction for a write operation (hereinafter referred to as “write instruction”) received from the control circuit 12, and executes the write operation. In the write operation, the write control circuit 115 writes data received from the storage circuit 15, or data read from another information processor 11, into an address designated by the write instruction.

The erase control circuit 116 controls the plane, based on an instruction for an erase operation (hereinafter referred to as “erase instruction”) received from the control circuit 12, and executes the erase operation. In the erase operation, the erase control circuit 116 erases data of an address (for example, block BLK) designated by the erase instruction. The erase control circuit 116 may be configured to be capable of erasing data stored in a specific memory cell.

The output storage register 117 stores an output value of each sense amplifier unit SAU of the sense amplifier module 113. In the semiconductor device 10 according to the first embodiment, the result of the logical operation is obtained as the output value of the sense amplifier unit SAU in the read operation.

The register output circuit 118 executes an operation relating to an output of the result of the logical operation stored in the output storage register 117. The value stored in the output storage register 117 is output via the register output circuit 118.

### <1-1-4> Circuit Configuration of Memory Cell Array 110

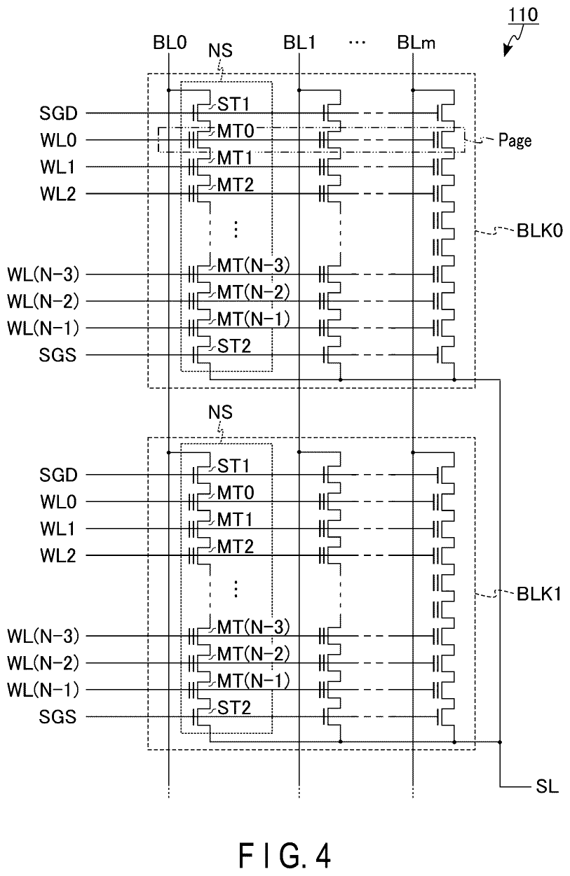

FIG. 4 is a circuit diagram illustrating an example of a circuit configuration of the memory cell array 110 included in the semiconductor device 10 according to the first embodiment. FIG. 4 illustrates two blocks BLK0 and BLK1 among the blocks BLK included in the memory cell array 110. As illustrated in FIG. 4, in the memory cell array 110, for example, select gate lines SGD and SGS and word lines WL0 to WL(N−1) (N is an integer of 2 or more) are provided for each block BLK. Bit lines BL0 to BLm and a source line SL are shared by, for example, a plurality of blocks BLK.

Each block BLK includes a plurality of NAND strings NS. The plurality of NAND strings NS are associated with the bit lines BL0 to BLm, respectively. Each NAND string NS is coupled between the associated bit line BL and source line SL. Each NAND string NS includes, for example, N memory cell transistors MT0 to MT(N−1) and select transistors ST1 and ST2. Each memory cell transistor MT is a memory cell including a control gate and a charge storage layer, and holds (stores) data in a nonvolatile manner. Each of the select transistors ST1 and ST2 is used to select the block BLK.

In each NAND string NS, the select transistor ST1, the memory cell transistors MT0 to MT(N−1), and the select transistor ST2 are coupled in series in the named order. Specifically, the drain and the source of the select transistor ST1 are coupled to the associated bit line BL and the drain of the memory cell transistor MT0, respectively. The drain and the source of the select transistor ST2 are coupled to the source of the memory cell transistor MT(N−1) and the source line SL, respectively. The memory cell transistors MT0 to MT(N−1) are coupled in series between the select transistors ST1 and ST2.

Each select gate line SGD is coupled to the gate of each of the select transistors ST1 included in the associated block BLK. The select gate line SGS is coupled to the gate of each of the select transistors ST2 included in the associated block BLK. The word lines WL0 to WL(N−1) are coupled to the control gates of the memory cell transistors MT0 to MT(N−1) included in the associated block BLK, respectively. The “page” corresponds to a set of memory cell transistors MT coupled to a common word line WL in the same block BLK.

Note that the circuit configuration of the memory cell array 110 may be another circuit configuration. A plurality of independently controllable select gate lines SGD may be provided in each block BLK. In this case, each block BLK is configured such that selection can be performed in units of a plurality of units individually associated with the select gate lines SGD. In the case where each block BLK includes a plurality of select gate lines SGD, the number of data of voltages of the select gate lines SGD, which are included in the read instruction corresponding to the logical operation, corresponds to a product between the number of blocks BLK and the number of select gate lines SGD in the block BLK.

### <1-2> Operation

Next, an operation of the semiconductor device 10 according to the first embodiment is described.

### <1-2-1> Information Processing

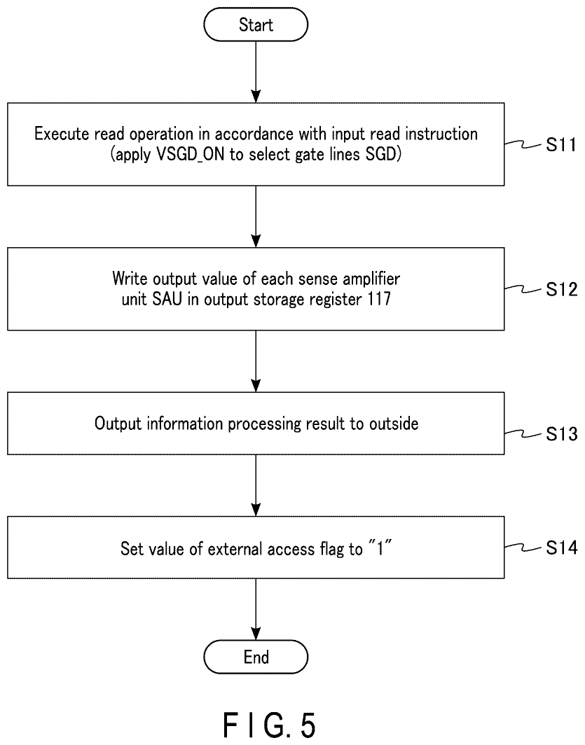

FIG. 5 is a flowchart illustrating an example of information processing of the semiconductor device 10 according to the first embodiment. The semiconductor device 10 according to the first embodiment executes information processing as a logical operation utilizing the plane. The control circuit 12 of the semiconductor device 10 according to the first embodiment receives, for example, a read instruction corresponding to a logical operation from the host device 20, and starts a series of processing illustrated in FIG. 5, based on a change of the value of the external access flag of the external access management circuit 14 from “1” to “0” (Start).

To start with, the control circuit 12 executes the read operation in accordance with the input read instruction (step S11). The read operation corresponds to the logical operation utilizing the plane. In the read operation, the read control circuit 114 applies voltage VSGD ON to a plurality of select gate lines SGD. In the read operation, the select transistor ST1, to the gate of which the voltage VSGD ON is applied, enters an ON state. In the read operation executed in the information processing (logical operation), it suffices that the voltage VSGD ON is applied to two or more select gate lines SGD in accordance with the content of the logical operation. The details of the read operation corresponding to the logical operation will be described later.

Next, the control circuit 12 writes the output value of each sense amplifier unit SAU in the output storage register 117 (step S12). Specifically, at first, the result of the read operation executed in step S11, that is, the result of the logical operation utilizing the plane (hereinafter referred to as “information processing result”), is read out to each sense amplifier unit SAU. Then, the information processing result is transferred from each sense amplifier unit SAU to the output storage register 117, and stored in the output storage register 117.

Subsequently, the control circuit 12 outputs the information processing result to the outside (step S13). Specifically, the information processing result stored in the output storage register 117 is output to the host device 20 via the register output circuit 118 and the input/output circuit 16.

Next, the control circuit 12 changes the value of the external access flag of the external access management circuit 14 from “0” to “1” (step S14). If the process of step S14 is completed, the control circuit 12 terminates the series of processing illustrated in FIG. 5 (End).

### <1-2-2> Read Operation

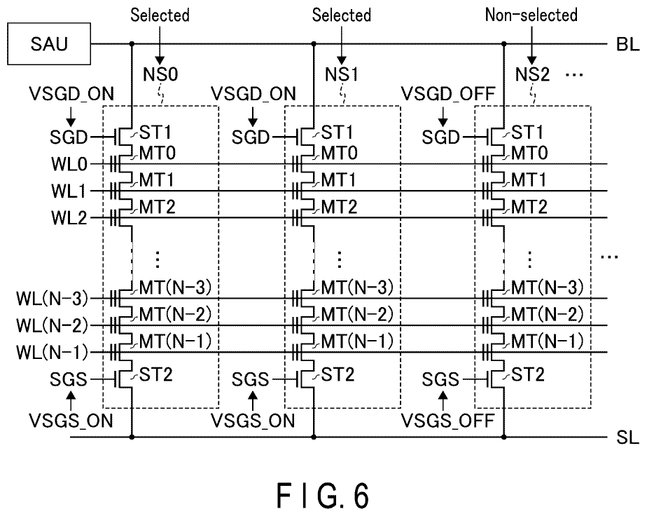

FIG. 6 is a schematic diagram illustrating an example of a read operation of the semiconductor device 10 according to the first embodiment. FIG. 6 illustrates voltages applied to three NAND strings NS0 to NS2 coupled to the same bit line BL, in the read operation corresponding to the logical operation. In the present example, the NAND strings NS0 to NS2 belong to mutually different blocks BLK. In the read operation corresponding to the logical operation, since word lines WL provided in the same layer between blocks BLK are controlled by the same potential, each word line WL is illustrated as being shared by the NAND strings NS. As illustrated in FIG. 6, in the present example, the NAND strings NS0 and NS1 are selected as operation targets, and the NAND string NS2 is non-selected.

The selected NAND string NS includes, in the read operation thereof, at least one memory cell transistor MT that is a target of read of a threshold voltage. The non-selected NAND string NS does not include, in the read operation thereof, a memory cell transistor MT that is a target of read of a threshold voltage.

In this case, the voltage VSGD ON is applied to the select gate line SGD of each of the selected NAND strings NS0 and NS1, and voltage VSGD OFF is applied to the select gate line SGD of the non-selected NAND string NS2. In the read operation, the select transistor ST1, to the gate of which the voltage VSGD ON is applied, enters the ON state, and the select transistor ST1, to the gate of which the voltage VSGD OFF is applied, enters the OFF state. In other words, the voltage that turns on the select transistor ST1 is applied to the select gate line SGD corresponding to the selected NAND string NS, and the voltage that turns off the select transistor ST1 is applied to the select gate line SGD corresponding to the non-selected NAND string NS.

In addition, voltage VSGS ON is applied to the select gate line SGS of each of the selected NAND strings NS0 and NS1, and voltage VSGS OFF is applied to the select gate line SGS of each of the non-selected NAND string NS2. In the read operation, the select transistor ST2, to the gate of which the voltage VSGS ON is applied, enters the ON state, and the select transistor ST2, to the gate of which the voltage VSGS OFF is applied, enters the OFF state. Note that in the read operation, the voltage VSGS ON may be applied to the select gate line SGS of each NAND string NS, regardless of the selection or non-selection of the NAND string NS.

In addition, for example, a voltage corresponding to a query is applied to each word line WL. Specifically, a voltage, which is associated with a bit of a query of a comparison target, is applied to each of the word lines WL0 to WL(N−1) of the selected NAND string NS on a word line WL by word line WL basis. Then, if the query coincides with all data of the selected NAND string NS, current flows via the NAND string NS between the bit line BL and the source line SL. In addition, a voltage for comparing data in the selected NAND string NS may be applied to each word line WL. The details regarding this will be described in a fourth embodiment.

As described above, in the read operation, such a state occurs that current via each of the selected NAND strings NS0 and NS1 can flow between the bit line BL and the source line SL in accordance with the voltage applied to each word line. On the other hand, such a state occurs that current via the non-selected NAND string NS2 does not flow between the bit line BL and the source line SL. As a result, the result of the logical operation using the data stored in the selected NAND string NS is read out to the bit line BL, according to whether current flows in the NAND string NS0, and according to whether current flows in the NAND string NS1.

### <1-3> Advantageous Effects of First Embodiment

According to the semiconductor device 10 of the first embodiment, an efficient logical operation using a memory device can be achieved. Hereinafter, the details of the advantageous effects of the first embodiment are described.

In the read operation of the NAND flash memory, normally, one select gate line SGD is selected. Then, a read voltage is applied to one word line WL that is coupled to the memory cell transistor MT of the read target, and a read pass voltage is applied to all of the other word lines WL. Specifically, in the normal read operation, one NAND string NS for each bit line BL is set in a conductive or non-conductive state between the bit line BL and the source line SL in accordance with the threshold voltage of the memory cell transistor MT of the read target.

On the other hand, the semiconductor device 10 according to the first embodiment includes a similar structure (the plane of the information processor 11) to a NAND flash memory, and is configured to be capable of executing a read operation corresponding to a logical operation. The content of the logical operation is determined based on the value of the input read instruction and the value of the threshold voltage of the memory cell transistor MT, which is set prior to the read operation. In addition, in the read operation corresponding to the logical operation, unlike the read operation of an ordinary NAND flash memory, NAND strings of a plurality of blocks BLK coupled to the same bit line BL can be rendered conductive at the same time.

As described above, the semiconductor device 10 according to the first embodiment can execute a logical operation by using the plane of the information processor 11. In addition, the semiconductor device 10 can achieve a greater storage capacity since the memory cells have a three-dimensionally stacked configuration, and can handle more complex logical operations and data than an existing field programmable gate array (FPGA). Moreover, compared to an SRAM (Static Random Access Memory)-based FPGA, the semiconductor device 10 can execute a large volume of logical operations at low power consumption. Therefore, the semiconductor device 10 according to the first embodiment can achieve an efficient logical operation using a memory device.

### <2> Second Embodiment

In a second embodiment, each information processor 11 of the semiconductor device 10 is configured to execute a next read operation, based on a read result. Hereinafter, an information processing system 1 according to the second embodiment is described mainly on different points from the first embodiment.

### <2-1> Configuration

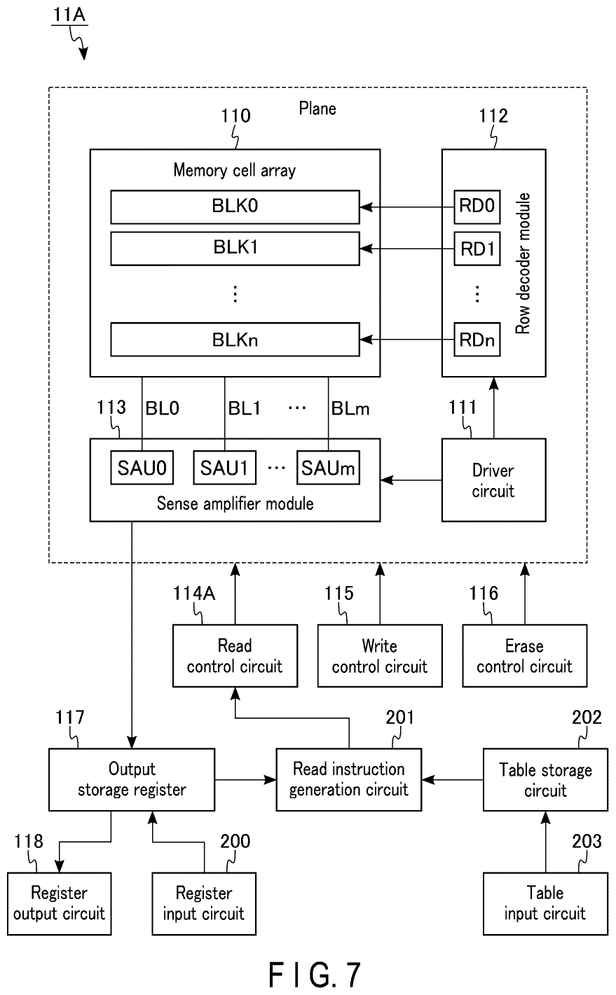

FIG. 7 is a block diagram illustrating an example of a configuration of an information processor 11A included in the semiconductor device 10 according to the second embodiment. As illustrated in FIG. 7, compared to the information processor 11 of the first embodiment, the information processor 11A is configured such that the read control circuit 114 is replaced with a read control circuit 114A, and a register input circuit 200, a read instruction generation circuit 201, a table storage circuit 202 and a table input circuit 203 are added.

The read control circuit 114A executes a read operation, based on a read instruction generated by the read instruction generation circuit. If the read control circuit 114A executes the read operation based on the read instruction, on the basis of a clock input from the control circuit, a read result is output to the sense amplifier module 113. Then, an output value of each sense amplifier unit SAU of the sense amplifier module 113 is stored in the output storage register 117. In the semiconductor device 10 according to the second embodiment, the output value of each sense amplifier unit SAU, which is obtained by the read operation, may include information that becomes a basis of the read instruction.

The register input circuit 200 is configured to input, for example, information relating to data and a first read instruction, to the output storage register 117. The control circuit 12 of the second embodiment inputs at least a part of the first read instruction to the register input circuit 200, and causes the output storage register 117 to store at least the part of the first read instruction. The “first read instruction” corresponds to a read instruction that is input from the outside of the information processor 11A, in regard to a plurality of times of logical operations (read operations) that the read control circuit 114A can execute in the second embodiment.

The read instruction generation circuit 201 generates a read instruction, based on the information that becomes the basis of the read instruction stored in the output storage register 117, and the information (read instruction correspondence table) stored in the table storage circuit 202. Then, the read instruction generation circuit 201 outputs the generated read instruction to the read control circuit 114A. The read instruction that is generated by the read instruction generation circuit 201 may not necessarily be a complete read instruction, but may be a subset of a read instruction. The read instruction generation circuit 201 may update the subset of the read instruction, and may utilize the value of the read instruction, which is received from the control circuit 12, for a missing part.

The table storage circuit 202 is a storage circuit such as a register or a memory. The table storage circuit 202 stores the read instruction correspondence table that is input from the table input circuit 203. The read instruction correspondence table stores information in which the value of the bit stored in the output storage register 117 is made to correspond to the value of the bit of the read instruction. Note that the correspondence may not be one-to-one correspondence. For example, in a case where the number of bits of the information that is the basis of the read instruction stored in the output storage register 117 is less than the number of bits of the read instruction, one-to-one correspondence cannot be obtained. In such a case, the read instruction generation circuit 201 may determine the values of a plurality of bits of the read instruction, based on the value of a certain bit of the output storage register 117.

The table input circuit 203 inputs the read instruction correspondence table to the table storage circuit 202. The table input circuit 203 may acquire the read instruction correspondence table by reading out the read instruction correspondence table from a predetermined address of a specific memory cell array 110, or by reading out the read instruction correspondence table from another storage device included in the semiconductor device 10.

Note that in the semiconductor device 10 according to the second embodiment, data is written in the plane of each information processor 11 such that a read result includes a next read instruction. In the information processor 11A, data, as well as the next read instruction, may be added to the read result from each plane. The added data can be output to the outside of the information processor 11A via the register output circuit 118. The other configuration of the information processing system 1 according to the second embodiment is similar to that of the information processing system 1 according to the first embodiment.

### <2-2> Operation

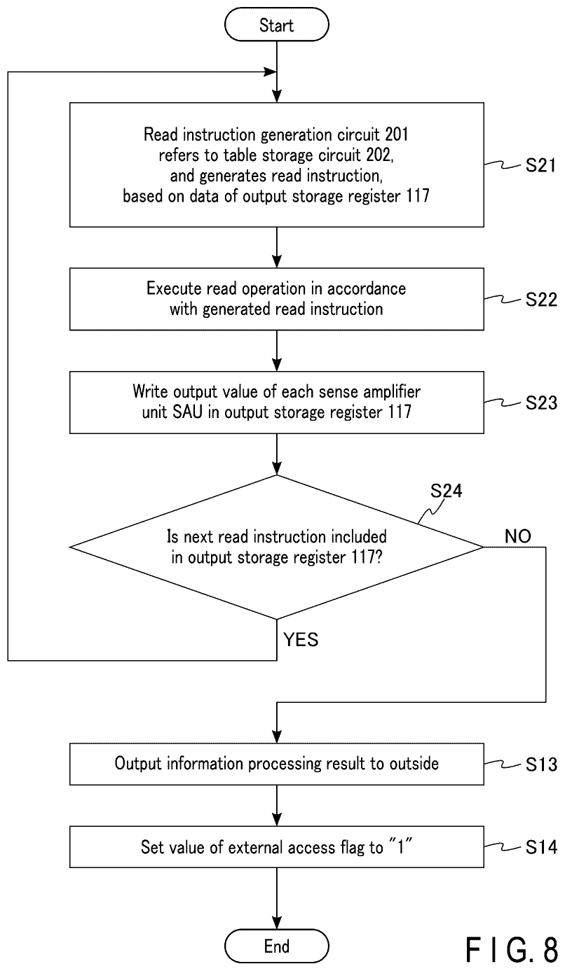

FIG. 8 is a flowchart illustrating an example of information processing of the semiconductor device 10 according to the second embodiment. The control circuit 12 of the semiconductor device 10 according to the second embodiment receives, for example, a read instruction corresponding to a logical operation from the host device 20, writes a first read instruction in the output storage register 117, and starts a series of processing illustrated in FIG. 8, based on a change of the value of the external access flag of the external access management circuit 14 from “1” to “0” (Start).

To begin with, the read instruction generation circuit 201 refers to the table storage circuit 202, and generates a read instruction, based on the data of the output storage register 117 (step S21). The read instruction generation circuit 201 may acquire the data relating to the read instruction by referring to a predetermined address, or may detect the data relating to the read instruction, based on a predetermined character string. The read instruction generation circuit 201 extracts an instruction corresponding to the data of the output storage register 117, from the read instruction correspondence table in the table storage circuit 202, and generates the read instruction.

Next, the read control circuit 114A executes the read operation in accordance with the read instruction generated by the read instruction generation circuit 201 (step S22). The details of the read operation executed in step S22 are similar to those of the read operation corresponding to the logical operation described in step S11 of FIG. 5.

Next, the control circuit 12 writes the output value of each sense amplifier unit SAU in the output storage register 117 (step S23). Specifically, at first, the result of the read operation executed in step S22, that is, the information processing result, is read out to each sense amplifier unit SAU. Then, the information processing result is transferred from each sense amplifier unit SAU to the output storage register 117, and stored in the output storage register 117. The information processing result in the second embodiment may include the data of the logical operation and the read instruction.

Next, the read instruction generation circuit 201 confirms whether or not the next read instruction is included in the output storage register 117 (step S24).

If the next read instruction is included in the output storage register 117 (step S24: YES), the control circuit 12 advances to the process of step S21. Specifically, the read control circuit 114A executes the read operation based on the next read instruction included in the output storage register 117, and writes the output value of each sense amplifier unit SAU based on the execution result into the output storage register 117. The control circuit 12 repeats the process of steps S21 to S24 until the next read instruction is not included in the output storage register 117.

If the next read instruction is not included in the output storage register 117 (step S24: NO), the control circuit 12 advances to the process of step S13. In the process of step S13, like the first embodiment, the control circuit 12 outputs the information processing result to the outside. In addition, like the first embodiment, the control circuit 12 changes the value of the external access flag of the external access management circuit 14 from “0” to “1” (step S14). If the process of step S14 is completed, the control circuit 12 terminates the series of processing illustrated in FIG. 8 (End).

Note that the read instruction may include a reception flag. The reception flag indicates whether the output storage register 117 accepts an input. For example, the reception flag is configured such that the reception flag can be read from the outside of the information processor 11 but cannot be written from the outside of the information processor 11. A read instruction other than the reception flag can be written from the outside in a case where the reception flag is a value corresponding to ON. In addition, the read instruction may include an operation flag. The operation flag indicates whether a read operation is executed at the next clock. For example, the operation flag enables an operation result at a previous clock to be executed at a later clock that is not immediately after the previous clock. The output storage register 117, in which the read instruction is already written, is configured such that, for example, only the operation flag can be rewritten at a later clock. The operation flag may be rewritten by an input from the outside, or may be rewritten based on an output from the plane. The read instruction that is read from the plane may include a read instruction for another information processor 11. In this case, a read instruction that is read from the plane of a a certain information processor 11 is transferred to the output storage register 117 of another information processor 11.

### <2-3> Advantageous Effects of Second Embodiment

In the semiconductor device 10 according to the second embodiment, the output of each sense amplifier unit SAU in the read operation includes the next read instruction, and the semiconductor device 10 includes the function of storing the next read instruction in the output storage register 117. In addition, the semiconductor device 10 according to the second embodiment treats the read result as a read instruction in the next and following clocks, and executes a read operation corresponding to a logical operation.

Thereby, the semiconductor device 10 according to the second embodiment can successively execute desired arithmetic operation processes in each information processor 11A. As a result, the semiconductor device 10 according to the second embodiment can carry out a logical operation using a memory device, more efficiently than in the first embodiment. In addition, each information processor 11A of the semiconductor device 10 according to the second embodiment can feed back a read result of a certain NAND string NS to a read operation in a different block BLK or a different plane. As a result, the semiconductor device 10 according to the second embodiment can execute a more complex logical operation by utilizing a plurality of information processors 11A.

### <3> Third Embodiment

In a third embodiment, the control circuit 12 of the semiconductor device 10 is configured to execute a logical operation, based on a read result of each information processor 11. Hereinafter, an information processing system 1 according to the third embodiment is described mainly on different points from the first and second embodiments.

### <3-1> Configuration

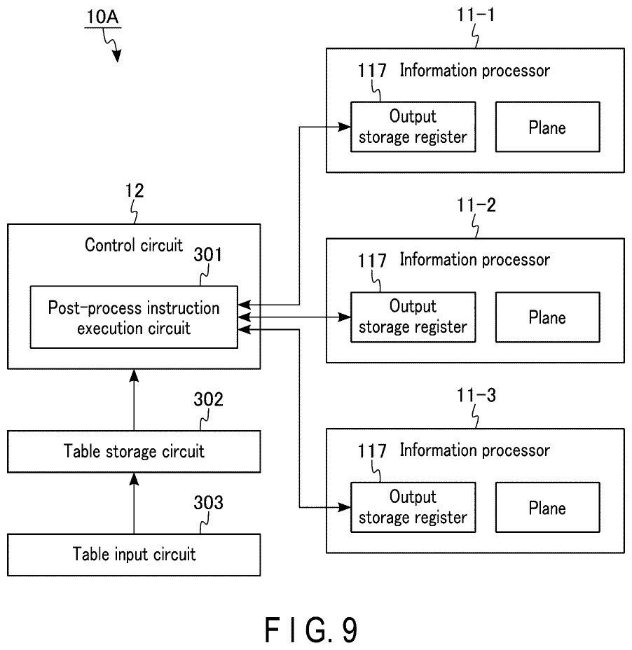

FIG. 9 is a block diagram illustrating an example of a configuration of a semiconductor device 10A according to the third embodiment. As illustrated in FIG. 9, compared to the semiconductor device 10 according to the first embodiment, the semiconductor device 10A is configured such that the control circuit 12 includes a post-process instruction execution circuit 301, and a table storage circuit 302 and a table input circuit 303 are added. Note that in FIG. 9, illustration of a part of the configuration of the semiconductor device 10A is omitted.

The post-process instruction execution circuit 301 generates a post-process instruction, based on information (a result of a read operation) stored in the output storage register 117 of each information processor 11, and executes a post-process, based on the generated post-process instruction. The post-process executed by the post-process instruction execution circuit 301 may be a one-time arithmetic operation, or a plurality of kinds of arithmetic operations. The output storage register 117 of the third embodiment can store information that becomes a basis of an instruction corresponding to an arithmetic operation that is executed as a post-process. The post-process is, for example, a process of writing an absolute value of the value stored in a certain register on the register, back to the same register, a process of writing the sum of a value A and a value B on the register back to the value A, or a process of regarding a set of data (hereinafter referred to as “dataset”) as a vector and calculating an inner product of a plurality of datasets. The post-process may be data write and data read for a volatile memory (for example, the storage circuit 15), or data write and data read for a nonvolatile memory (for example, the memory cell array 110).

The table storage circuit 302 is a storage circuit such as a register or a memory. The table storage circuit 302 stores a post-process instruction correspondence table that is input from the table input circuit 303. The post-process instruction correspondence table stores information in which the value of the bit stored in the output storage register 117 is made to correspond to the value of the bit of the post-process instruction. Note that the correspondence may not be one-to-one correspondence. For example, in a case where the number of bits of the information that becomes the basis of the post-process instruction stored in the output storage register 117 is less than the number of bits of the post-process instruction, one-to-one correspondence cannot be obtained. In such a case, the post-process instruction execution circuit 301 may determine the values of a plurality of bits of the post-process instruction, based on the value of a certain bit of the output storage register 117.

The table input circuit 303 inputs the post-process instruction correspondence table to the table storage circuit 302. The table input circuit 303 may acquire the post-process instruction correspondence table by reading out the post-process instruction correspondence table from a predetermined address of a specific memory cell array 110, or by reading out the post-process instruction correspondence table from another storage device included in the semiconductor device 10A.

Note that the semiconductor device 10A may generate a read instruction for a specific information processor 11, based on the post-process instruction, and may cause the corresponding output storage register 117 to store the read instruction. The post-process instruction execution circuit 301 may execute the logical operation using each information processor 11, and a post-process that the post-process instruction execution circuit 301 itself executes, by using the storage circuit 15 as a working area. The other configuration of the information processing system 1 according to the third embodiment is similar to that of the information processing system 1 according to the first embodiment.

### <3-2> Operation

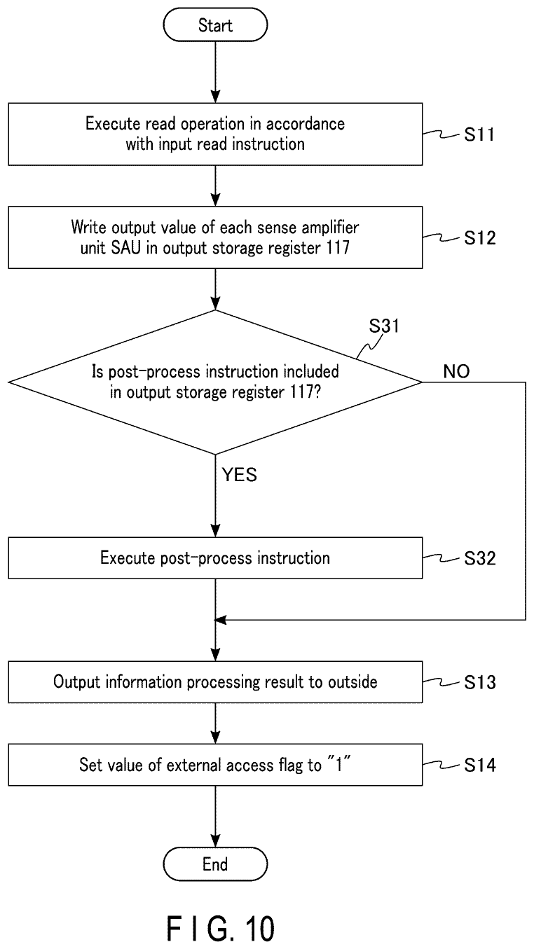

FIG. 10 is a flowchart illustrating an example of information processing of the semiconductor device 10A according to the third embodiment. The control circuit 12 of the semiconductor device 10A according to the third embodiment receives, for example, a read instruction corresponding to a logical operation from the host device 20, and starts a series of processing illustrated in FIG. 10, based on a change of the value of the external access flag of the external access management circuit 14 from “1” to “0” (Start).

To start with, like the first embodiment, the control circuit 12 executes the read operation in accordance with the input read instruction (step S11).

Next, like the first embodiment, the control circuit 12 writes the output value of each sense amplifier unit SAU into the output storage register 117 (step S12).

Subsequently, the control circuit 12 confirms whether the post-process instruction is included in the output storage register 117 (step S31). Specifically, the post-process instruction execution circuit 301 first acquires, from the post-process instruction correspondence table, an address of a register in which the post-process instruction can be stored, in the output storage register 117 of the information processor 11 that has executed the read operation. Then, the post-process instruction execution circuit 301 refers to the data stored in the address in which the post-process instruction can be stored in the output storage register 117, and confirms the presence or absence of the post-process instruction.

If the post-process instruction is not included in the output storage register 117 (step S31: NO), the control circuit 12 advances to the process of step S13.

If the post-process instruction is included in the output storage register 117 (step S31: YES), the post-process instruction execution circuit 301 of the control circuit 12 executes the post-process instruction (step S32). The post-process instruction may utilize, for example, the operation result stored in the output storage register 117 that stores the post-process instruction, or may utilize the data stored in another block BLK or plane. If the process of step S32 is completed, the control circuit 12 advances to the process of step S13. Note that the process of step S32 may be completed based on the post-process instruction that finishes the post-process.

In the process of step S13, like the first embodiment, the control circuit 12 outputs the information processing result to the outside. Then, like the first embodiment, the control circuit 12 changes the value of the external access flag of the external access management circuit 14 from “0” to “1” (step S14). If the process of step S14 is completed, the control circuit 12 terminates the series of processing illustrated in FIG. 10 (End).

Note that the post-process instruction may include a read operation and a write operation for each information processor 11. In the post-process instruction, after a designated logical operation is executed, the operation result may be written in the output storage register 117 of the information processor 11 designated by the post-process instruction. In the process of step S32, in a case where a plurality of post-process instructions are included in the output storage register 117, the post-process instruction execution circuit 301 may execute all the post-process instructions included in the output storage register 117. In addition, in a case where the address of the next post-process instruction is included in the post-process instruction executed in the process of step S32, the post-process instruction execution circuit 301 may acquire the next post-process instruction from the address of the next post-process instruction, and may execute the next post-process instruction.

### <3-3> Advantageous Effects of Third Embodiment

In the semiconductor device 10A according to the third embodiment, the output of each sense amplifier unit SAU in the read operation includes the post-process instruction that is executed by the post-process instruction execution circuit 301 on the outside of the information processor 11. In addition, the post-process instruction execution circuit 301 executes, for example, a logical operation that is low in efficiency if executed by each information processor 11.

Thereby, the semiconductor device 10A according to the third embodiment can execute a higher-level logical operation or can execute a higher-efficiency logical operation than in the case where only the information processor 11 is used. As a result, the semiconductor device 10A according to the third embodiment can achieve a logical operation using a memory device, more efficiently than in the first embodiment.

### <4> Fourth Embodiment

A fourth embodiment relates to a preparation for the semiconductor device 10 to execute a logical operation, and a specific example of a logical operation that the semiconductor 10 can execute. Hereinafter, an information processing system 1 according to the fourth embodiment is described mainly on different points from the first to third embodiments.

### <4-1> Configuration

A configuration of the information processing system 1 according to the fourth embodiment is similar to the configuration of the information processing system 1 according to the first embodiment. In addition, in the fourth embodiment, threshold voltage distribution of memory cell transistors MT, and allocation of data are applied as described below.

### (Threshold Voltage Distribution of Memory Cell Transistors MT)

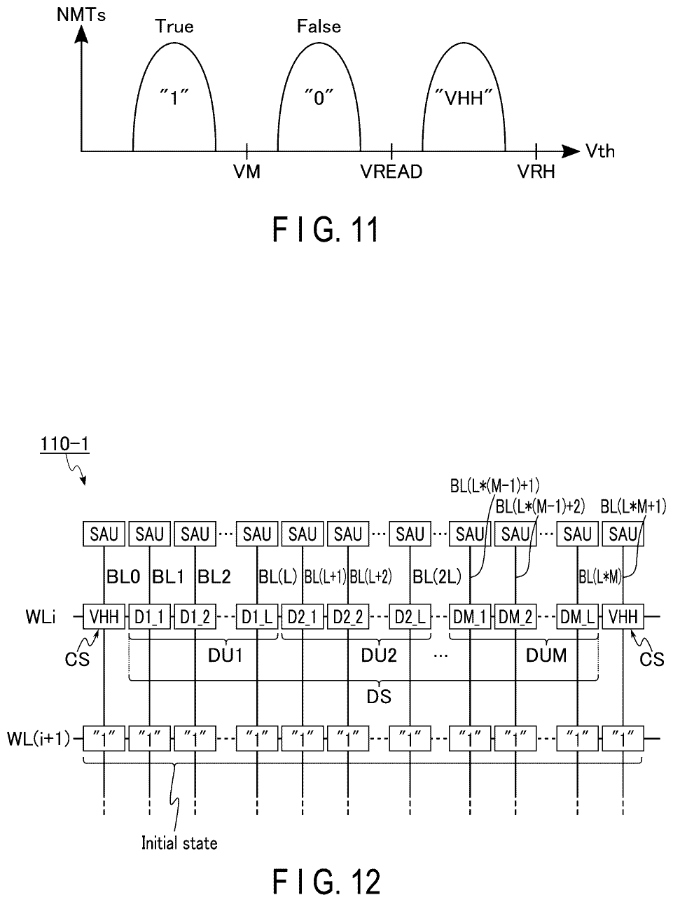

FIG. 11 is a schematic diagram illustrating an example of threshold voltage distribution of memory cell transistors MT included in the semiconductor device 10 according to the fourth embodiment. As illustrated in FIG. 11, “NMTs” on the vertical axis indicates the number of memory cell transistors MT. “Vth” on the horizontal axis indicates the threshold voltage of the memory cell transistors MT. As illustrated in FIG. 11, in the semiconductor device 10 according to the fourth embodiment, the threshold voltage distribution of the memory cell transistors MT can form three states. In the present specification, the three states are referred to as state “1”, state “0” and state “VHH” in order from a lower threshold voltage.

“1” data (True) is allocated to the state “1”. “0” data (False) is allocated to the state “0”. Each of “1” data and “0” data is used as valid data. Invalid data is allocated to the state “VHH”. The memory cell transistor MT having a threshold voltage of the “VHH” state can be used as a reference indicating a division point of datasets to be described later.

A read voltage VM is set between the state “1” and the state “0”. A read pass voltage VREAD is set between the state “0” and the state “VHH”. A read pass voltage VRH is set at a voltage higher than the state “VHH”. If the read voltage VM is applied, the memory cell transistor MT enters an ON state or an OFF state in accordance with stored data. If the read pass voltage VREAD is applied, the memory cell transistor MT storing valid data enters the ON state, and the memory cell transistor MT storing invalid data enters the OFF state. If the read pass voltage VRH is applied, the memory cell transistor MT enters the ON state, regardless of the stored data.

The value of the threshold voltage corresponding to the data written in the memory cell transistor MT is determined in accordance with the content of the logical operation, for example, by the software such as a compiler or a linker, which is executed by the host device 20. The host device 20 stores the determined value of the threshold voltage of the memory cell transistor MT into an electronic file or the like as a memory image. Then, the host device 20 reads the electronic file or the like of the memory image by software such as a loader, and inputs the information to the semiconductor device 10.

The semiconductor device 10 causes a predetermined memory cell transistor MT to store the value of the threshold voltage of the memory cell transistor MT designated by the host device 20, by an erase operation or a write operation of a well-known NAND flash memory. In the semiconductor device 10, the memory cell transistor MT that stores data used in a logical operation stores data by two values (“1” data and “0” data illustrated in FIG. 11). In addition, in a case where the semiconductor device 10 treats data of 2k value (k is an integer of 1 or more), the data is coded by a k page of an SLC (Single Level Cell). Specifically, 8-value data is coded by three pages of the SLC. In the case of coding by three pages of the SLC, one data is expressed by 3-bit data stored in three memory cell transistors MT in total. In a case where complementary data used for a logical operation to be described later is stored in the memory cell array 110, the number of memory cell transistors MT for storing data of a 2k value is k×2. In the present specification, the complementary data corresponds to data in which 0 or 1 is inverted.

### <4-2> Operation

Next, an operation of the semiconductor device 10 according to the fourth embodiment is described. In the semiconductor device 10 according to the fourth embodiment, mutually different roles are assigned to the information processors 11-1, 11-2 and 11-3. The memory cell arrays 110 of the information processors 11-1, 11-2 and 11-3 are referred to as memory cell arrays 110-1, 110-2 and 110-3, respectively. In addition, hereinafter, a case is described in which purchase data is used as data handled in information processing. The purchase data is, for example, data of L bits (L is an integer of 2 or more) including a personal code, a region code, an age code and a gender code. In the drawings to be referred to below, illustration of the select transistors ST1 and ST2 and select gate lines SGD and SGS is omitted.

### <4-1-1> Storage Process

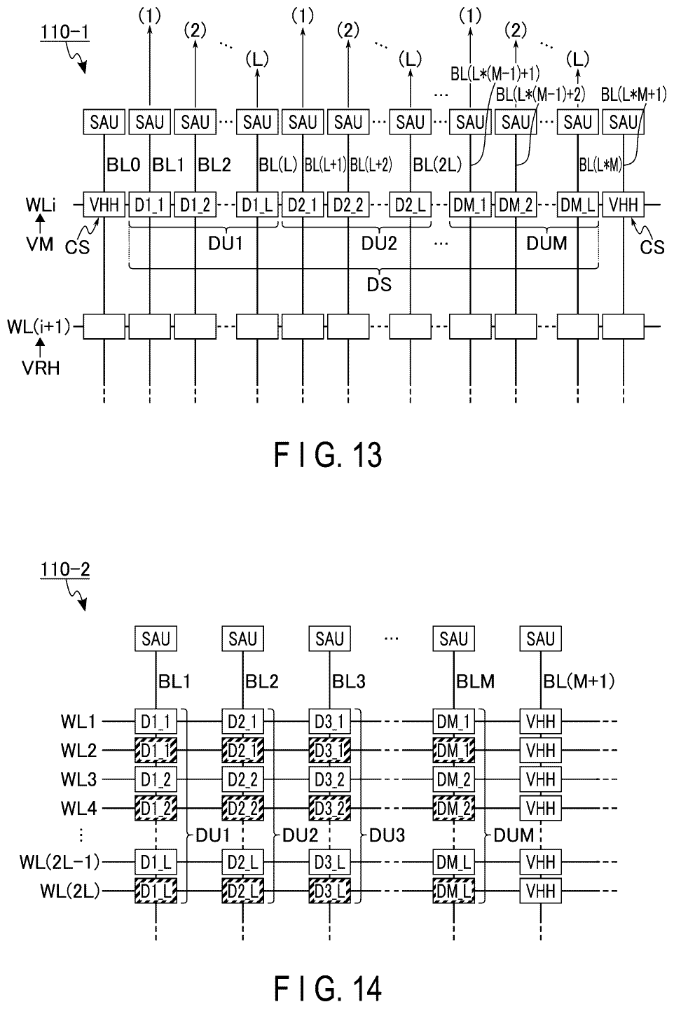

The semiconductor device 10 according to the fourth embodiment executes a storage process, for example, as the preparation for executing a logical operation utilizing a plane. Hereinafter, the storage process of the semiconductor device 10 is described with reference to FIG. 12, FIG. 13 and FIG. 14.

Each of FIG. 12, FIG. 13 and FIG. 14 is a schematic diagram illustrating a specific example of the storage process of the semiconductor device 10 according to the fourth embodiment. Each of FIG. 12 and FIG. 13 illustrates a plurality of sense amplifier units SAU, a plurality of bit lines BL, word lines WLi and WL(i+1) (i is an integer of 0 or more), and data stored in memory cell transistors MT, which are associated with a certain block BLK of the memory cell array 110-1. FIG. 14 illustrates a plurality of sense amplifier units SAU, a plurality of bit lines BL, word lines WL1 to WL (2L), and data stored in memory cell transistors MT, which are associated with a certain block BLK of the memory cell array 110-2. The content of data stored in the memory cell transistor MT is indicated at an intersection between the word line WL and the bit line BL.

To begin with, as illustrated in FIG. 12, the control circuit 12 causes the memory cell array 110-1 of the information processor 11-1 to store purchase data. In the present example, the memory cell transistors MT coupled to the word line WL(i+1) correspond to an initial state before data is stored by the storage process. The threshold voltage of each memory cell transistor MT in the initial state corresponds to the erase state. Specifically, each memory cell transistor MT in the initial state stores “1” data.

Purchase data is written in the memory cell transistors MT coupled to the word line WLi. The purchase data is written in the memory cell array 110-1 in the order of input. At a time of writing purchase data, the semiconductor device 10 converts the purchase data into a unit called “dataset DS”. The dataset DS is a set of purchase data collected under a predetermined condition. Each page can include a plurality of datasets DS. The dataset DS includes M (M is an integer of 2 or more) data units DU1 to DUM. The data unit DU includes L-bit data (L is an integer of 2 or more) associated with one purchase data.

The L-bit data included in the data unit DU is written, on a bit-by-bit basis, in the memory cell transistors MT associated with the same page and different bit lines BL. Specifically, the data unit DU1 includes, for example, data D1_1 to D1_L associated with bit lines BL1 to BL(L). The data unit DU2 includes, for example, data D2_1 to D2_L associated with bit lines BL(L+1) to BL(2L). Similarly, the data unit DUM includes, for example, data DM_1 to DM_L associated with bit lines BL(L*(M−1)+1) to BL(L*M). Each data included in the data unit DU is “1” data or “0” data.

The beginning and the end of each dataset DS are discriminated by the memory cell transistors MT that are written in the “VHH” state. In the present example, the memory cell transistor MT coupled to the bit line BL0 and the word line WLi and the memory cell transistor MT coupled to the bit line BL(L*M+1) and the word line WLi are written in the “VHH” state as division cells CS. If purchase data is successively input, the division cell CS is inserted, for example, as a division point of a unit of a day.

Note that a plurality of datasets DS may be stored in each page of the memory cell array 110-1. The size of each of the dataset DS and the data unit DU may be changed in accordance with the kind of data to be treated. If the kind of data is identical, the size of the data unit DU is made uniform. On the other hand, the size of the dataset DS is changeable in accordance with the number of data units DU that are included. The position of the division cell CS may be identical for each word line WL, or may be different between word lines WL.

Next, as illustrated in FIG. 13, the control circuit 12 reads purchase data from the memory cell array 110-1 of the information processor 11-1, and writes the purchase data in the memory cell array 110-2 of the information processor 11-2, as illustrated in FIG. 14.

To begin with, in a case of reading the page including the dataset DS, the read control circuit 114 of the information processor 11-1 applies the read pass voltage VREAD to the word line WLi of the read target. Then, the latch circuit of the sense amplifier unit SAU coupled to the bit line BL, in which cell current via the NAND string NS does not flow, latches (holds) this information. Thereby, the position of the division (division cell CS) of the dataset DS is stored in the sense amplifier module 113. Note that the read control circuit 114 applies the read pass voltage VRH to the word line WL (for example, WL(i+1)) that is not the read target. Thereby, the memory cell transistors MT coupled to the word line WL that is not the read target enter the ON state regardless of the state of the threshold voltage.

Then, the read control circuit 114 of the information processor 11-1 applies the read voltage VM to the word line WLi, and reads the dataset DS from the first bit in units of L bits. The data read in units of L bits is transferred to the information processor 11-2. Then, the write control circuit 115 of the information processor 11-2 writes the data, which is read in units of L bits, for example, into the first word line WL in order of bit lines BL. In the present example, the bit line BL1 is used as the first bit line BL. In addition, the write control circuit 115 of the information processor 11-2 writes complementary data of the data, which is read in units of L bits, into the next word line WL. This operation is executed for each bit included in the data unit DU.

Specifically, the data D1_1 of the data unit DU1, the data D2_1 of the data unit DU2, . . . the data DM_1 of the data unit DUM, which are stored in the memory cell array 110-1, are read ((1) in FIG. 13). As illustrated in FIG. 14, the read data D1_1, D2_1, . . . , data DM_1 are written in the page corresponding to the word line WL1 of the memory cell array 110-2. The complementary data of the data D1_1, D2_1, . . . , data DM_1 are written in the page corresponding to the word line WL2 of the memory cell array 110-2. Note that in FIG. 14, the memory cell transistors MT, in which the complementary data is written, are distinguished by hatching.

The data D1_2 of the data unit DU1, the data D2_2 of the data unit DU2, . . . , the data DM_2 of the data unit DUM, which are stored in the memory cell array 110-1, are read ((2) in FIG. 13). As illustrated in FIG. 14, the read data D1_2, D2_2, . . . , data DM_2 are written in the page corresponding to the word line WL3 of the memory cell array 110-2. The complementary data of the data D1_2, D2_2, . . . , data DM_2 are written in the page corresponding to the word line WL4 of the memory cell array 110-2.

Similarly, the data D1_L of the data unit DU1, the data D2_L of the data unit DU2, . . . , the data DM_L of the data unit DUM are read ((L) in FIG. 13). As illustrated in FIG. 14, the read data D1_L, D2_L, . . . , data DM_L are written in the page corresponding to the word line WL2 (2L−1) of the memory cell array 110-2. The complementary data of the data D1_L, D2_L, . . . , data DM_L are written in the page corresponding to the word line WL (2L) of the memory cell array 110-2.

Thereby, in the memory cell array 110-2, the data units DU1 to DUM are associated with the bit lines BL1 to BLM. The initial state of each memory cell transistor MT of the memory cell array 110-2 is set to the threshold voltage of the state “VHH”. Thus, the threshold voltage of each memory cell transistor MT of the NAND string NS coupled to the bit line BL(M+1) is the state “VHH”.

As has been described above, in the storage process, the purchase data written in the page in the memory cell array 110-1 is converted to vertical writing in the memory cell array 110-2. In addition, in the memory cell array 110-2, the data is written in a complementary form. Thus, the data unit DU, which is the L-bit unit in the memory cell array 110-1, is changed to a 2L-bit unit in the memory cell array 110-2. Note that the read operation of the memory cell array 110-1 for the data input to the memory cell array 110-2 may be executed before the data input to the memory cell array 110-1 is finished. The settings of the first word line WL and the first bit line BL can be changed as appropriate.

### <4-1-2> Comparison Process

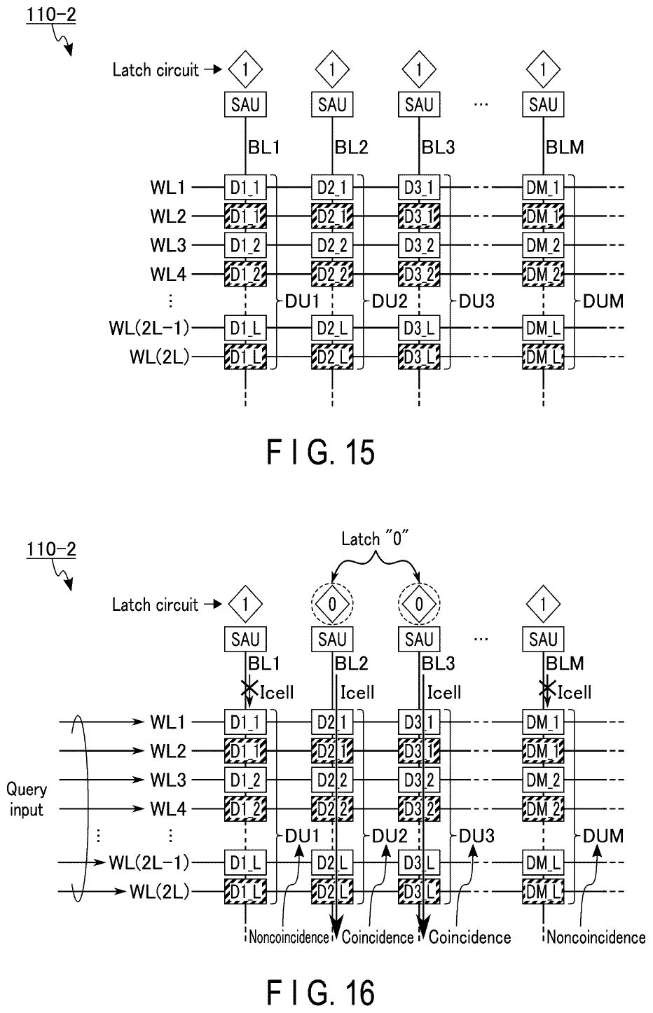

The semiconductor device 10 according to the fourth embodiment executes, for example, a comparison process as an operation of comparing the purchase data stored in the plane, and a query. The comparison process can be used in a search under a designated condition from the host device 20. Hereinafter, referring to FIG. 15 and FIG. 16, the comparison process of the semiconductor device 10 is described.

Each of FIG. 15 and FIG. 16 is a schematic diagram illustrating a specific example of a comparison process of the semiconductor device 10 according to the fourth embodiment. Each of FIG. 15 and FIG. 16 illustrates a plurality of sense amplifier units SAU, a plurality of bit lines BL, word lines WL1 to WL (2L), and data stored in memory cell transistors MT, which are associated with a certain block BLK of the memory cell array 110-2. The content of the data stored in the memory cell transistors MT is the same as in FIG. 14. In addition, each of FIG. 15 and FIG. 16 illustrates the data stored in the latch circuit of each sense amplifier unit SAU.

As illustrated in FIG. 15, before the comparison process is executed, all latch circuits of the sense amplifier units SAU store “1” data. The memory cell array 110-2 stores purchase data in a case where the number of purchased goods of a certain purchaser is to be totalized. As illustrated in FIG. 16, in the comparison process, a voltage corresponding to coding of a purchaser condition is applied as an external query to a selected word line WL or selected word lines WL. For example, the read voltage VM is associated with “1” data. The read voltage VREAD is associated with “0” data. In addition, VREAD is applied to a word line WL corresponding to a condition to which attention is not paid. If the data corresponding to the voltage applied to the selected word line WL coincides with the data stored in the memory cell transistor MT, the memory cell transistor MT enters the ON state. On the other hand, if the data corresponding to the voltage applied to the selected word line WL does not coincide with the data stored in the memory cell transistor MT, the memory cell transistor MT enters the OFF state.

Note that to the memory cell transistor MT in which the complementary data is stored, for example, a voltage corresponding to the complementary data of the associated query is applied. Specifically, in the present example, the voltage applied to the word line WL1 and the voltage applied to the word line WL2 have a complementary relation. The voltage applied to the word line WL (2L−1) and the voltage applied to the word line WL (2L) have a complementary relation. In the present example, the read voltage VM and the read voltage VREAD are defined to have a complementary relation. Specifically, in a case where a certain query is “1” data, the voltage applied to the word line WL having a complementary relation is VREAD. In a case where a certain query is “0” data, the voltage applied to the word line WL having a complementary relation is VM. Note that the read voltage VREAD may be applied to the memory cell transistor MT in which the complementary data is stored, regardless of the data of the associated query.

As a result, cell current Icell flows through the NAND string NS that stores the data unit DU in which the query and the data coincide. Cell current Icell does not flow through the NAND string NS that stores the data unit DU in which the query and the data do not coincide. In other words, the NAND string NS in which the Icell is ON agrees with the query. The NAND string NS in which the Icell is OFF does not agree with the query. In addition, the cell current Icell does not flow in the NAND string NS in which data is not written, since this NAND string NS is composed of the memory cell transistors of the state “VHH”. FIG. 16 illustrates the case in which each of the data units DU2 and DU3 agrees with the query, and each of the data units DU1 and DUM does not agree with the query. In addition, each sense amplifier unit SAU latches (stores) “0” data in a case where the sense amplifier unit SAU is coupled to the bit line BL in which the cell current Icell flows.

If the comparison process is completed, the data (the result of the comparison process) stored in the latch circuit of each sense amplifier unit SAU is transferred to the output storage register 117. Then, the result of the comparison process is output from the output storage register 117 to the outside via the register output circuit 118. Thereafter, the number of “0” data in the result of the comparison process output to the outside is counted by, for example, the control circuit 12. Note that the counting of the result of the comparison result may be executed by a counter provided in the information processor 11 or the like.

### <4-1-3> Addition Process

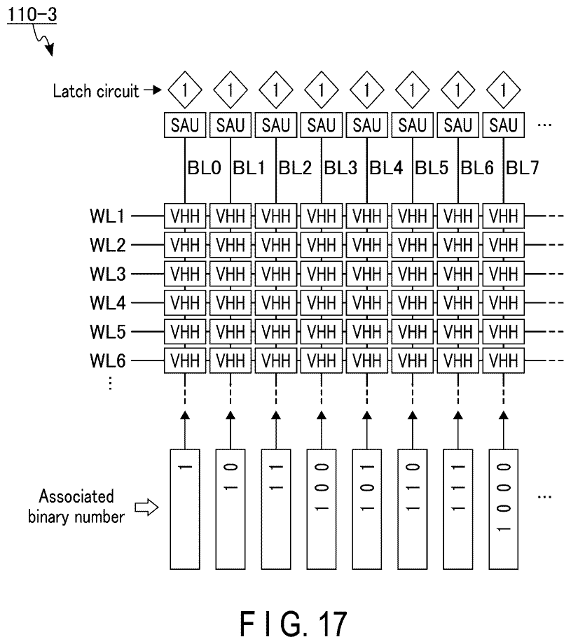

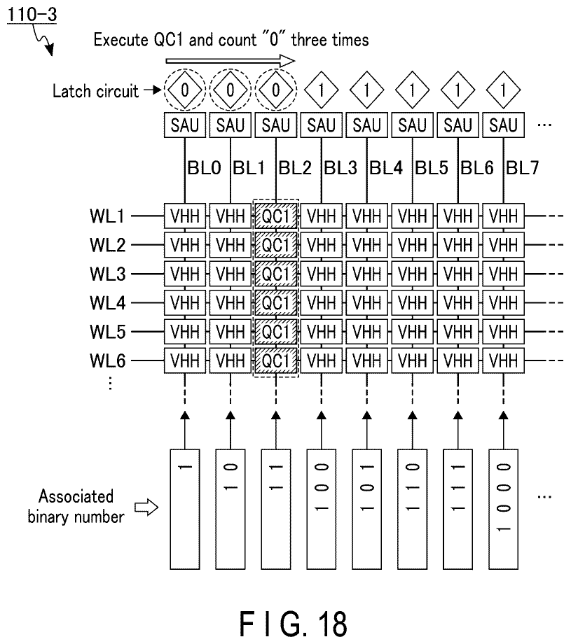

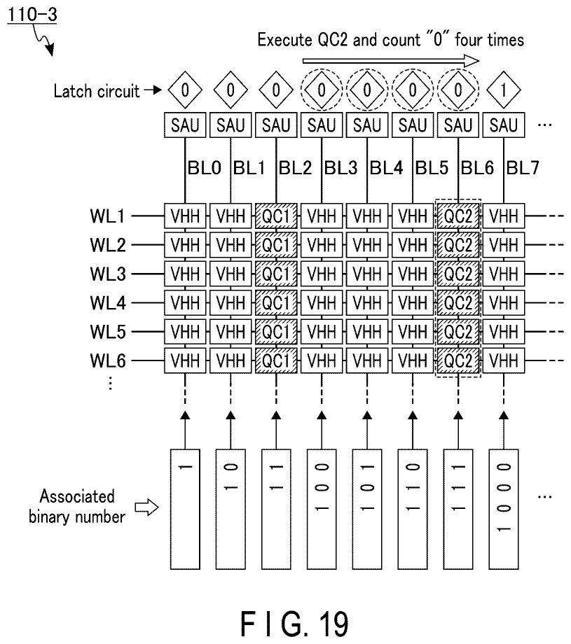

The semiconductor device 10 according to the fourth embodiment executes, for example, an addition process as an operation of recording information obtained by the comparison process. Hereinafter, referring to FIG. 17, FIG. 18 and FIG. 19, the addition process of the semiconductor device 10 is described.

Each of FIG. 17, FIG. 18 and FIG. 19 is a schematic diagram illustrating a specific example of an addition process of the semiconductor device 10 according to the fourth embodiment. Each of FIG. 17, FIG. 18 and FIG. 19 illustrates a plurality of sense amplifier units SAU, a plurality of bit lines BL, word lines WL1 to WL6, and data stored in memory cell transistors MT, which are associated with a certain block BLK of the memory cell array 110-3. In addition, each of FIG. 17, FIG. 18 and FIG. 19 illustrates the data stored in the latch circuit of each sense amplifier unit SAU.

As illustrated in FIG. 17, the initial state of each memory cell transistor MT of the memory cell array 110-3 is set to, for example, the threshold voltage of the state “VHH”. In addition, all latch circuits of the sense amplifier units SAU store “1” data. Further, each bit line BL is associated with a binary number. For example, a first bit line BL0 is associated with a binary number “1”. A second bit line BL1 is associated with a binary number “10”. A third bit line BL2 is associated with a binary number “11”. A fourth bit line BL3 is associated with a binary number “100”. A fifth bit line BL4 is associated with a binary number “101”. A sixth bit line BL5 is associated with a binary number “110”. A seventh bit line BL6 is associated with a binary number “111”. An eighth bit line BL7 is associated with a binary number “1000”. Similarly, subsequent bit lines BL are associated with binary numbers. The first bit line BL may be changed.

In the addition process, the control circuit 12 first inputs the result of a comparison process of a query QC1 to the information processor 11-3, and causes the latch circuits to store “0” data in order (for example, from the left to the right in FIG. 18). In addition, a code of the query QC1 is written to the bit line BL coupled to the right-end sense amplifier unit SAU that latches the “0” data. Next, the control circuit 12 inputs the result of a comparison process of a query QC2 to the information processor 11-3, and causes the latch circuits to store “0” data in order from the latch circuit next to the latch circuit in which the “0” data was stored. Then, a code of the query QC2 is written to the bit line BL coupled to the right-end sense amplifier unit SAU that latches the “0” data. Subsequently, the addition process is similarly executed as many times as the number of queries QC that are the targets of the addition process.

For example, “0” data is counted three times by the comparison process using the query QC1. In this case, as illustrated in FIG. 18, the information processor 11-3 causes the latch circuits of the three sense amplifiers SAU coupled to three bit lines BL(bit lines BL0 to BL2) from the first bit line BL to store “0” data. In addition, the code of the query QC1 is stored in the NAND string NS coupled to the bit line BL2 that is coupled to the sense amplifier unit SAU that stores “0” data last. In the present example, the code of the query QC1 is written in six memory cell transistors MT coupled to the word lines WL1 to WL6 of the NAND string NS coupled to the bit line BL2.

Thereafter, “0” data is counted four times by the comparison process using the query QC2. In this case, as illustrated in FIG. 19, the information processor 11-3 causes the latch circuits of the four sense amplifiers SAU to store “0” data, the four sense amplifiers SAU being coupled to four bit lines BL(bit lines BL3 to BL6) from the bit line BL3 next to the bit line BL2 to which the sense amplifier unit SAU storing “0” data is coupled. In addition, the code of the query QC2 is stored in the NAND string NS coupled to the bit line BL6 that is coupled to the sense amplifier unit SAU that stores “0” data last. In the present example, the code of the query QC2 is written in six memory cell transistors MT coupled to the word lines WL1 to WL6 of the NAND string NS that is coupled to the bit line BL6.

As described above, if the comparison result using each query QC is successively recorded in the latch circuits, the binary number associated with the bit line BL coupled to the right-end sense amplifier unit SAU storing “O” data corresponds to the sum of count results of each query QC. For example, the sum of “0” data counts based on the queries QC1 and QC2 can be obtained based on the binary number (111) associated with the bit line BL6.

Note that the value of the associated binary number may be stored in the memory cell transistor MT of a predetermined address of the memory cell array 110-3. In this case, the control circuit 12 can acquire the value of the binary number associated with each bit line BL, by reading out data from the predetermined address. In addition, the result of the comparison process, i.e., the count result of the number of latch circuits in which “0” data is latched in the comparison process, is input to the information processor 11-3.

<4-1-4> Exclusive OR (XOR) Process Next, an exclusive OR (XOR) process of the semiconductor device 10 according to the fourth embodiment is described.

### (Data Arrangement Method)

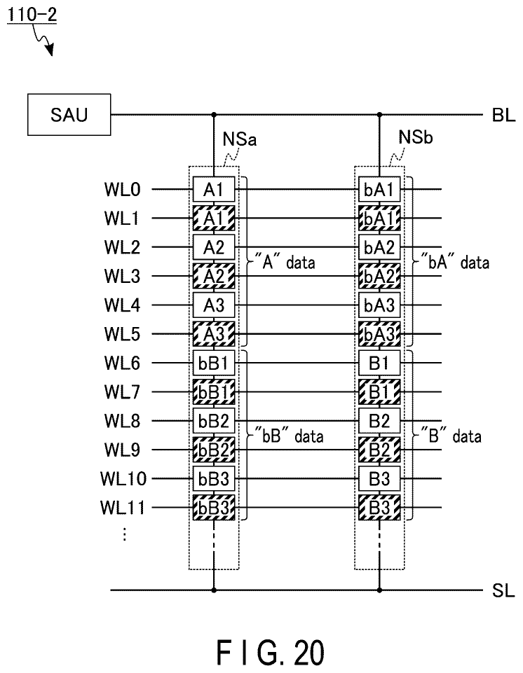

FIG. 20 is a schematic diagram illustrating an example of a method of arranging data in the memory cell array 110 included in the semiconductor device 10 according to the fourth embodiment. FIG. 20 illustrates two NAND strings NSa and NSb coupled to the bit line BL that is coupled to a certain sense amplifier unit SAU of the memory cell array 110-2, word lines WL0 to WL11, a source line SL, and data stored in the memory cell transistors MT. Note that in FIG. 20, the memory cell transistors MT, in which the complementary data is written, are distinguished by hatching.

As illustrated in FIG. 20, the NAND string NSa stores “A” data and “bB” data, and the NAND string NSb stores “bA” data and “B” data. The “bA” data corresponds to complementary data of the “A” data. The “bB” data corresponds to complementary data of the “B” data. In the present example, each of the “A” data and the “B” data is composed of 3-bit data. Specifically, the “A” data is composed of “A1” data, “A2” data and “A3” data stored in mutually different memory cell transistors MT. The “B” data is composed of “B1” data, “B2” data and “B3” data stored in mutually different memory cell transistors MT. In addition, in the present example, as described with reference to FIG. 14, complementary data is stored for each data. Note that the complementary data of the “bA” data is the “A” data. The complementary data of the “bB” data is the “B” data.

The word lines WL0 to WL5 associated with the memory cell transistors MT storing the “A” data in the NAND string NSa are shared by the memory cell transistors MT storing the “bA” data in the NAND string NSb. The word lines WL6 to WL11 associated with the memory cell transistors MT storing the “bB” data in the NAND string NSa are shared by the memory cell transistors MT storing the “B” data in the NAND string NSb.

Specifically, in the NAND string NSa, “A1”, “A2” and “A3” data are stored in the three memory cell transistors MT coupled to the word lines WL0, WL2 and WL4, respectively. In the NAND string NSa, complementary data of the “A1”, “A2” and “A3” data are stored in the three memory cell transistors MT coupled to the word lines WL1, WL3 and WL5, respectively. In the NAND string NSa, “bB1”, “bB2” and “bB3” data are stored in the three memory cell transistors MT coupled to the word lines WL6, WL8 and WL10, respectively. In the NAND string NSa, complementary data of the “bB1”, “bB2” and “bB3” data are stored in the three memory cell transistors MT coupled to the word lines WL7, WL9 and WL11, respectively.

On the other hand, in the NAND string NSb, “bAl”, “bA2” and “bA3” data are stored in the three memory cell transistors MT coupled to the word lines WL0, WL2 and WL4, respectively. In the NAND string NSb, complementary data of the “bA1”, “bA2” and “bA3” data are stored in the three memory cell transistors MT coupled to the word lines WL1, WL3 and WL5, respectively. In the NAND string NSb, “B1”, “B2” and “B3” data are stored in the three memory cell transistors MT coupled to the word lines WL6, WL8 and WL10, respectively. In the NAND string NSb, complementary data of the “B1”, “B2” and “B3” data are stored in the three memory cell transistors MT coupled to the word lines WL7, WL9 and WL11, respectively.

As has been described above, the data stored in each of the NAND strings NSa and NSb is composed of a pair. By this data arrangement, the control circuit 12 can execute an XOR process and an XNOR process between the “A” data and the “B” data. Note that in the above-described data arrangement, the first word line WL may not be the word line WL0, and may be changed. In a case where the XOR process or XNOR process between the data including the “A” data and the “B” data is executed, the complementary data of a plurality of data including the “B” data are stored in the NAND string NSa, and a plurality of data including the “B” data are stored in the NAND string NSb.

### (Specific Example of XOR Process)

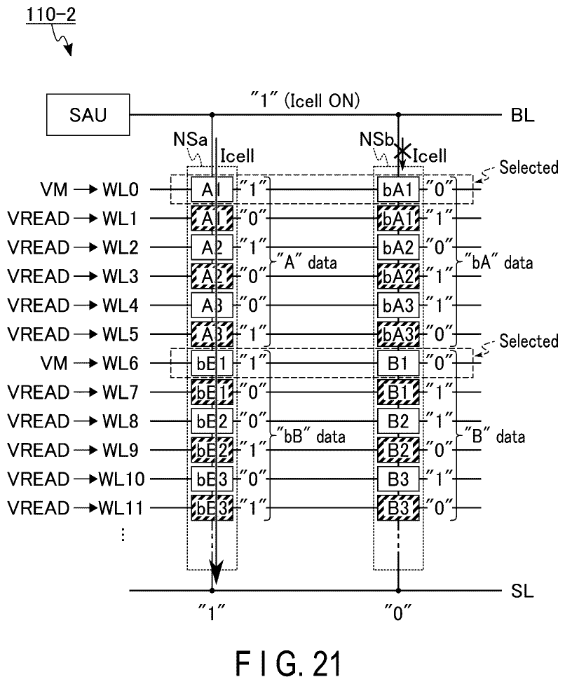

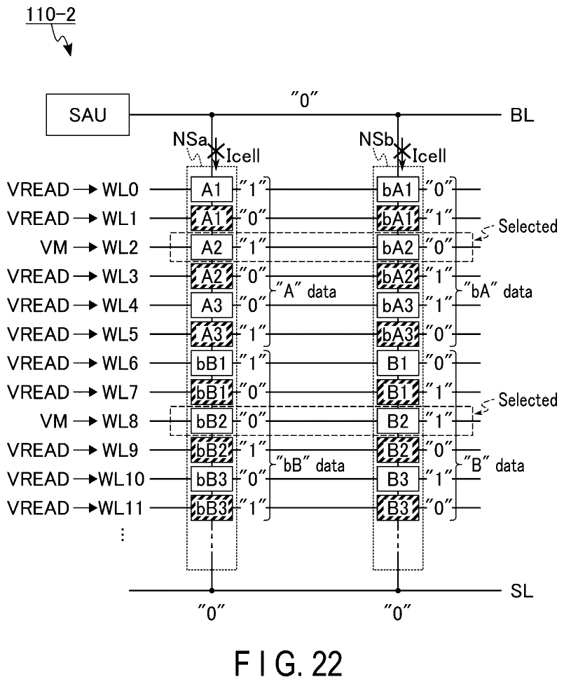

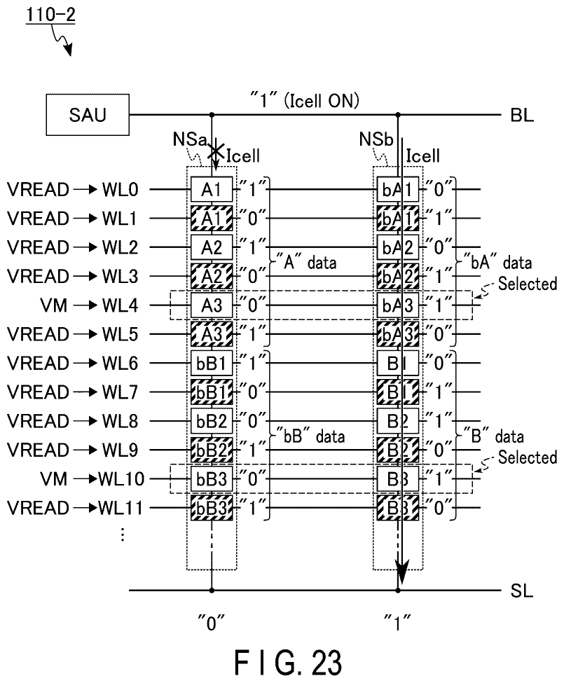

Each of FIG. 21, FIG. 22 and FIG. 23 is a schematic diagram illustrating a specific example of an exclusive OR process of the semiconductor device 10 according to the fourth embodiment. Each of FIG. 21, FIG. 22 and FIG. 23 illustrates a similar configuration to FIG. 20, and voltages applied to the word lines WL. Hereinafter, a case is described in which an XOR process between “A” data and

“B” data is executed in a case where “A1”, “A2” and “A3” data are “1”, “1” and “0” data, respectively, and “B1”, “B2” and “B3” data are “0”, “1” and “1” data, respectively.

To begin with, the control circuit 12 executes a read operation for targets that are the “A1” data of the source of comparison and the “B1” data of the destination of comparison. Specifically, as illustrated in FIG. 21, a read operation is executed in which the word line WL0, to which the memory cell transistor MT storing the “A1” data is coupled, and the word line WL6, to which the memory cell transistor MT storing the “B1” data is coupled, are selected. In the read operation executed in the XOR process, the read voltage VM is applied to the selected word lines WL, and the read pass voltage VREAD is applied to the non-selected word lines WL. In other words, the read voltage VM is applied to each of the word lines WL0 and WL6, and the read pass voltage VREAD is applied to the other word lines WL.

Then, in the NAND string NSa, by the application of the read voltage VM, the memory cell transistor MT storing the “A1” data (= “1” data), and the memory cell transistor MT storing the “bB1” data (= “1” data), enter the ON state. On the other hand, in the NAND string NSb, by the application of the read voltage VM, the memory cell transistor MT storing the “bA1” data (= “0” data), and the memory cell transistor MT storing the “B1” data (= “0” data), enter the OFF state.

As a result, cell current Icell via the NAND string NSa flows between the bit line BL and source line SL, and cell current Icell via the NAND string NSb does not flow. Specifically, the read result of the NAND string NSa corresponds to “1” data, and the read result of the NAND string NSb corresponds to “0” data. In addition, the sense amplifier unit SAU detects that cell current Icell has flown in at least one NAND string NS, and latches the “1” data (Icell ON) that is the result of the XOR operation between the “1” data and the “0” data.

Next, the control circuit 12 executes a read operation for targets that are the “A2” data of the source of comparison and the “B2” data of the destination of comparison. Specifically, as illustrated in FIG. 22, a read operation is executed in which the word line WL2, to which the memory cell transistor MT storing the “A2” data is coupled, and the word line WL8, to which the memory cell transistor MT storing the “B2” data is coupled, are selected. In other words, the read voltage VM is applied to each of the word lines WL2 and WL8, and the read pass voltage VREAD is applied to the other word lines WL.

Then, in the NAND string NSa, by the application of the read voltage VM, the memory cell transistor MT storing the “A2” data (= “1” data) enters the ON state, and the memory cell transistor MT storing the “bB2” data (= “0” data) enters the OFF state. On the other hand, in the NAND string NSb, by the application of the read voltage VM, the memory cell transistor MT storing the “bA2” data (= “0” data) enters the OFF state, and the memory cell transistor MT storing the “B2” data (= “1” data) enters the ON state.

As a result, neither the cell current Icell via the NAND string NSa nor the cell current Icell via the NAND string NSb flows between the bit line BL and source line SL. Specifically, the read result of each of the NAND string NSa and the NAND string NSb corresponds to “0” data. In addition, the sense amplifier unit SAU detects that cell current Icell did not flow and latches the “0” data that is the result of the XOR operation between the “1” data and the “1” data.

Next, the control circuit 12 executes a read operation for targets that are the “A3” data of the source of comparison and the “B3” data of the destination of comparison. Specifically, as illustrated in FIG. 23, a read operation is executed in which the word line WL4, to which the memory cell transistor MT storing the “A3” data is coupled, and the word line WL10, to which the memory cell transistor MT storing the “B3” data is coupled, are selected. In other words, the read voltage VM is applied to each of the word lines WL4 and WL10, and the read pass voltage VREAD is applied to the other word lines WL.

Then, in the NAND string NSa, by the application of the read voltage VM, each of the memory cell transistor MT storing the “A3” data (= “0” data) and the memory cell transistor MT storing the “bB3” data (= “0” data) enters the OFF state. On the other hand, in the NAND string NSb, by the application of the read voltage VM, each of the memory cell transistor MT storing the “bA3” data (= “1” data) and the memory cell transistor MT storing the “B3” data (= “1” data) enters the ON state.

As a result, the cell current Icell via the NAND string NSb flows between the bit line BL and source line SL, and the cell current Icell via the NAND string NSa does not flow. Specifically, the read result of the NAND string NSa corresponds to “0” data, and the read result of the NAND string NSb corresponds to “1” data. In addition, the sense amplifier unit SAU detects that cell current Icell has flown in at least one NAND string NS, and latches the “1” data (Icell ON) that is the result of the XOR operation between the “0” data and the “1” data.

As has been described above, in the XOR process, the read operation is executed by one bit (one word line WL) being selected for each of two data to be compared. Thereby, the difference between data is examined in units of one bit. The sense amplifier unit SAU latches “1” data in a case where there is a difference between two data to be compared, and laches “0” data in a case where the two data to be compared are identical. In the present example, since the number of times of latching of “0” data is one, it is determined that 2-bit data is different between the “A” data and the “B” data.

In the above description, the case was described in which the “A” data is composed of 3-bit data, but the embodiment is not limited to this. The “A” data may be one bit, two bit, or four or more bits. In the XOR process, the number of bits constituting the “A” data is set to be equal to the number of bits constituting the “B” data or the like that is the target of comparison.

### (Parallel Processing)

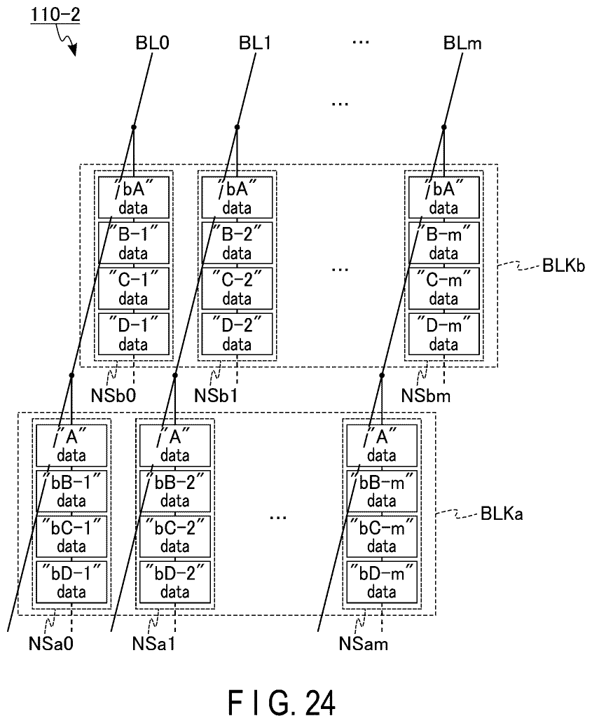

FIG. 24 is a schematic diagram illustrating an example of parallel processing of the exclusive OR (XOR) process of the semiconductor device 10 according to the fourth embodiment. In the case of executing the XOR process in parallel, data is arranged as illustrated in FIG. 24. Specifically, to begin with, two blocks BLKa and BLKb included in the blocks BLK of the memory cell array 110-2 are associated. The block BLKa includes a plurality of NAND strings NSa0, NSa1, NSa2, . . . , NSam. The block BLKb includes a plurality of NAND strings NSb0, NSb1, NSb2, . . . , NSbm. The NAND string NSa and NAND string NSb with the same numeral being added to the reference signs constitute a similar pair to the two NAND strings NSa and NSb illustrated in FIG. 20, and are coupled to the same bit line BL.

For example, “A” data, “bB-1” data, “bC-1” data and “bD-1” data are stored in the NAND string NSa0 in the named order. Complementary data of the data stored in the NAND string NSa0, i.e., “bA” data, “B-1” data, “C-1” data and “D-1” data, are stored in the NAND string NSb0 in the named order. “A” data, “bB-2” data, “bC-2” data and “bD-2” data are stored in the NAND string NSa1 in the named order. Complementary data of the data stored in the NAND string NSa1, i.e., “bA” data, “B-2” data, “C-2” data and “D-2” data, are stored in the NAND string NSb1 in the named order. Note that “B-j” data corresponds to data associated with the same word line WL, and may be different between bit lines BL. “C-j” data corresponds to data associated with the same word line WL, and may be different between bit lines BL. “D-j” data corresponds to data associated with the same word line WL, and may be different between bit lines BL.

Similarly, in each NAND string NSa, “A” data, and “bB” data, “bC” data and “bD” data, which are different between NAND strings NSa, are stored. On the other hand, in each NAND string NSb, “bA” data, and “B” data, “C” data and “D” data, which are different between NAND strings NSb, are stored.

By utilizing the above-described data arrangement, the control circuit 12 can simultaneously execute in parallel the XOR process between the “A” of the source of comparison and “B-1” to “B-m” data, “C-1” to “C-m” data, or “D-1” to “D-m” data, which are the destination of comparison. Specifically, parallel processing of large-scale data is enabled by the data arrangement of the memory cell array 110-2.

### <4-1-5> Exclusive NOR (XNOR) Process

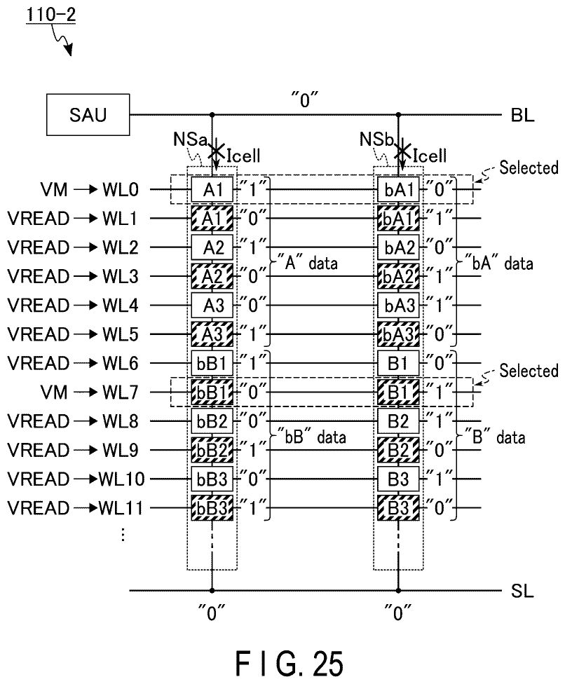

FIG. 25 is a schematic diagram illustrating a specific example of an exclusive NOR (XNOR) process of the semiconductor device according to the fourth embodiment. FIG. 25 illustrates a similar configuration to FIG. 20, and voltages applied to the word lines WL. Hereinafter, a case is described in which an XNOR process between “A” data and “B” data is executed in a case where “A1”, “A2” and “A3” data are “1”, “1” and “0” data, respectively, and “B1”, “B2” and “B3” data are “0”, “1” and “1” data, respectively. The XNOR process differs from the XOR process in that the word line WL selected in accordance with the target of comparison is changed to a word line WL that is associated with complementary data.

For example, the control circuit 12 executes a read operation for targets that are the “A1” data of the source of comparison and the “B1” data of the destination of comparison. Specifically, as illustrated in FIG. 25, a read operation is executed in which the word line WL0, to which the memory cell transistor MT storing the “A1” data is coupled, and the word line WL7, to which the memory cell transistor MT storing the complementary data of the “B1” data is coupled, are selected. In the read operation executed in the XNOR process, the read voltage VM is applied to the selected word lines WL, and the read pass voltage VREAD is applied to the non-selected word lines WL. In other words, the read voltage VM is applied to each of the word lines WL0 and WL7, and the read pass voltage VREAD is applied to the other word lines WL.

Then, in the NAND string NSa, by the application of the read voltage VM, the memory cell transistor MT storing the “A1” data (= “1” data) enters the ON state, and the memory cell transistor MT storing the complementary data (= “0” data) of the “bB1” data enters the OFF state. On the other hand, in the NAND string NSb, by the application of the read voltage VM, the memory cell transistor MT storing the “bA1” data (= “0” data) enters the OFF state, and the memory cell transistor MT storing the complementary data (= “1” data) of the “B1” data enters the ON state.

As a result, neither the cell current Icell via the NAND string NSa nor the cell current Icell via the NAND string NSb flows between the bit line BL and source line SL. Specifically, the read result of each of the NAND string NSa and the NAND string NSb corresponds to “0” data. In addition, the sense amplifier unit SAU detects that cell current Icell did not flow, and latches the “0” data that is the result of the XNOR operation between the “1” data and the “0” data.

Similarly, in the XNOR process, the read operation is executed by one bit (one word line WL) being selected for the data of the source of comparison and the complementary data of the destination of comparison. Thereby, the difference between the “A” data and the complementary data of the “B” data is examined in units of one bit. In addition, the sense amplifier unit SAU latches (stores) “0” data in a case where there is a difference between the data of the source of comparison and the complementary data of the data of the destination of comparison, and laches “1” data in a case where the data of the source of comparison and the complementary data of the data of the destination of comparison are identical.

In the above description, the case was described in which the “A” data is composed of 3-bit data, but the embodiment is not limited to this. The “A” data may be one bit, two bit, or four or more bits. In the XNOR process, the number of bits constituting the “A” data is set to be equal to the number of bits constituting the “B” data or the like that is the target of comparison. By the application of the data arrangement described with reference to FIG. 24, the XNOR process between the data of the source of comparison and the plural data of the destination of comparison can simultaneously be executed in parallel, like the XOR process.

### <4-3> Advantageous Effects of Fourth Embodiment

As has been described above, the semiconductor device 10 according to the fourth embodiment can execute the storage process for executing the logical operation. In addition, by utilizing the data that is rearranged by the storage process, the semiconductor device 10 according to the fourth embodiment can execute the comparison process, addition process, XOR process and XNOR process by read operations. In this manner, the semiconductor device 10 according to the fourth embodiment can execute various logical operations by utilizing the configuration of the NAND flash memory.

Furthermore, at a time of writing the purchase data in the memory cell array 110-2, the semiconductor device 10 according to the fourth embodiment causes each NAND string NS to also store complementary data. Thereby, the semiconductor device 10 according to the fourth embodiment can selectively execute the XOR process and the XNOR process by simply changing the word lines WL to be selected.

### <5> Modifications and the Like

The above-described information processing system 1 can variously be modified.

The host device 20 illustrated in FIG. 1 may be replaced with a memory controller that controls the semiconductor device 10. In this case, the memory controller controls the semiconductor device 10, based on an instruction from an external host device. In a case where the semiconductor device 10 does not include the function of executing a read instruction stored in the output storage register 117 as in the second embodiment, the read result including the read instruction may be output to such a memory controller. In addition, the memory controller may be configured to input to the semiconductor device 10 a read instruction based on a read instruction received from the semiconductor device 10. Similarly, in a case where the semiconductor device 10 does not include the function of executing a post-process instruction stored in the output storage register 117 as in the third embodiment, the read result including the post-process instruction may be output to the memory controller. In addition, the memory controller may be configured to execute the post-process instruction received from the semiconductor device 10, and to input the result of the post-process to the semiconductor device 10.

In the above-described embodiments, the flowcharts used in the description of operations are merely examples. In the flowcharts, other processes may be added. In the present specification, the term “couple” refers to electrical coupling, and does not exclude, for example, interposition of another element therebetween. “Electrically coupled” may be via an insulator if an operation is possible in the same manner as electrical coupling. The sense amplifier unit SAU may be configured to be capable of executing a simple arithmetic process. In the fourth embodiment, the case was illustrated in which the purchase data is used as the target data for the execution of the logical operation, but the embodiment is not limited to this. The target data for the execution of the logical operation may appropriately be changed in accordance with a user's request.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first bit line;
a plurality of strings coupled to the first bit line, each of the strings including a select transistor and a plurality memory cells, the select transistor and the memory cells being coupled in series; and
a first control circuit configured to execute a logical operation, wherein
in the logical operation, the first control circuit is configured to execute a read operation to apply a first voltage to the select transistors of at least two strings of the strings, to apply a second voltage lower than the first voltage to the select transistor of a string other than the at least two strings, to apply a third voltage to at least two memory cells of the memory cells of each of the strings, and to apply a fourth voltage higher than the third voltage to the memory cells other than the at least two memory cells.

2. The semiconductor device of claim 1, further comprising:
a plurality of bit lines including the first bit line, the strings being coupled to each of the bit lines;
a plurality of sense amplifiers coupled to the bit lines; and
an output storage register configured to store data that is output from each of the sense amplifiers, wherein
the first control circuit is further configured to execute, after the read operation is executed, a read instruction based on a read result stored in the output storage register.

3. The semiconductor device of claim 1, further comprising:
a plurality of bit lines including the first bit line, the strings being coupled to each of the bit lines;
a plurality of sense amplifiers coupled to the bit lines;
an output storage register configured to store data that is output from each of the sense amplifiers; and
a second control circuit configured to execute, after the read operation is executed, a post-process instruction including a logical operation, based on a read result stored in the output storage register.

4. The semiconductor device of claim 1, further comprising:
a first memory cell array and a second memory cell array, each of the first memory cell array and the second memory cell array is configured to store data in units of a page and includes the strings; and
a third control circuit configured to write input data in a first page of the first memory cell array, and to write the input data read from the first page into a first string included in the strings of the second memory cell array.

5. The semiconductor device of claim 4, wherein
the third control circuit is further configured to execute, in a case where a query is input from an outside, a read operation to apply a voltage based on the query to each of the memory cells of the first string.

6. The semiconductor device of claim 5, further comprising a third memory cell array coupled to a plurality of sense amplifiers each including a latch circuit, wherein
the third control circuit is further configured to:
count a number of first values obtained as a result of execution of the read operation based on a first query, and change, from a second value to a third value, a value stored in the latch circuits of a first number of sense amplifiers from a first sense amplifier of the sense amplifiers, the first number corresponding to a first count result based on the first query;
count the number of the first values obtained as a result of execution of the read operation based on a second query, and change, from the second value to the third value, a value stored in the latch circuits of a second number of sense amplifiers from a sense amplifier next to the sense amplifier in which the latch circuit stores the third value among the sense amplifiers, the second number corresponds to a second count result based on the second query; and
acquire a sum of the first count result and the second count result, in accordance with a binary number assigned to a last sense amplifier in which the latch circuit stores the third value.

7. The semiconductor device of claim 4, wherein
the third control circuit is further configured to further write, other than writing the input data read from the first page into the first string of the second memory cell array, complementary data of the input data into the first string.

8. The semiconductor device of claim 7, wherein
the strings of the second memory cell array further include a second string coupled to the same bit line as the first string, and
the third control circuit is further configured to write complementary data of the data stored in the first string into the second string.

9. The semiconductor device of claim 8, wherein
the third control circuit is further configured to execute an exclusive OR process,
the memory cells included in the first string include a first memory cell that stores first data, a second memory cell that stores complementary data of the first data, a third memory cell that stores complementary data of second data, and a fourth memory cell that stores the second data,
the memory cells included in the second string include a fifth memory cell that stores complementary data of the first data, a sixth memory cell that stores the first data, a seventh memory cell that stores the second data, and an eighth memory cell that stores complementary data of the second data, and
in the exclusive OR process, the third control circuit is further configured to apply the first voltage to the select transistors of the first string and the second string, to apply the third voltage to each of the first memory cell, the third memory cell, the fifth memory cell and the seventh memory cell, and to apply the fourth voltage to each of the second memory cell, the fourth memory cell, the sixth memory cell and the eighth memory cell.

10. The semiconductor device of claim 8, wherein
the third control circuit is further configured to execute an exclusive NOR process,
the memory cells included in the first string include a first memory cell that stores first data, a second memory cell that stores complementary data of the first data, a third memory cell that stores complementary data of second data, and a fourth memory cell that stores the second data,
the memory cells included in the second string include a fifth memory cell that stores complementary data of the first data, a sixth memory cell that stores the first data, a seventh memory cell that stores the second data, and an eighth memory cell that stores complementary data of the second data, and
in the exclusive NOR process, the third control circuit is configured to apply the first voltage to the select transistors of the first string and the second string, to apply the third voltage to each of the first memory cell, the fourth memory cell, the fifth memory cell and the eighth memory cell, and to apply the fourth voltage to each of the second memory cell, the third memory cell, the sixth memory cell and the seventh memory cell.

11. A non-transitory storage medium storing a program that controls a semiconductor device comprising a first bit line and a plurality of strings coupled to the first bit line, each of the strings including a select transistor and a plurality memory cells, the select transistor and the memory cells being coupled in series,
the program being configured to cause the semiconductor device to execute a read operation, the read operation including applying a first voltage to the select transistors of at least two strings of the strings, applying a second voltage lower than the first voltage to the select transistor of a string other than the at least two strings, applying a third voltage to at least two memory cells of the memory cells of each of the strings, and applying a fourth voltage higher than the third voltage to the memory cells other than the at least two memory cells.

12. The storage medium of claim 11, wherein
the semiconductor device further comprises:
a plurality of bit lines including the first bit line, the strings being coupled to each of the bit lines;
a plurality of sense amplifiers coupled to the bit lines; and
an output storage register configured to store data that is output from each of the sense amplifiers, and
the program is further configured to execute, after the read operation is executed, a read instruction based on a read result stored in the output storage register.

13. The storage medium of claim 11, wherein
the semiconductor device further comprises:
a plurality of bit lines including the first bit line, the strings being coupled to each of the bit lines;
a plurality of sense amplifiers coupled to the bit lines; and
an output storage register configured to store data that is output from each of the sense amplifiers, and
the program is further configured to execute, after the read operation is executed, a post-process instruction including a logical operation, based on a read result stored in the output storage register.

14. The storage medium of claim 11, wherein
the semiconductor device further comprises:
a first memory cell array and a second memory cell array, each of the first memory cell array and the second memory cell array includes the strings and is configured to store data in units of a page; and
the program is further configured to write input data in a first page of the first memory cell array, and to write the input data read from the first page into a first string included in the strings of the second memory cell array.

15. The storage medium of claim 14, wherein
the program is further configured to execute, in a case where a query is input from an outside, a read operation to apply a voltage based on the query to each of the memory cells of the first string.

16. The storage medium of claim 15, wherein
the semiconductor device further comprises a third memory cell array coupled to a plurality of sense amplifiers each including a latch circuit, and
the program is further configured to:
count a number of first values obtained as a result of execution of the read operation based on a first query, and change, from a second value to a third value, a value stored in the latch circuits of a first number of sense amplifiers from a first sense amplifier of the sense amplifiers, the first number corresponding to a first count result based on the first query;
count the number of the first values obtained as a result of execution of the read operation based on a second query, and change, from the second value to the third value, a value stored in the latch circuits of a second number of sense amplifiers from a sense amplifier next to the sense amplifier in which the latch circuit stores the third value among the sense amplifiers, the second number corresponds to a second count result based on the second query; and
acquire a sum of the first count result and the second count result, in accordance with a binary number assigned to a last sense amplifier in which the latch circuit stores the third value.

17. The storage medium of claim 14, wherein
the program is further configured to further write, at other than writing the input data read from the first page into the first string of the second memory cell array, complementary data of the input data into the first string.

18. The storage medium of claim 17, wherein
the strings of the second memory cell array further include a second string coupled to the same bit line as the first string, and
the program is further configured to write complementary data of the data stored in the first string into the second string.

19. The storage medium of claim 18, wherein
the memory cells included in the first string include a first memory cell that stores first data, a second memory cell that stores complementary data of the first data, a third memory cell that stores complementary data of second data, and a fourth memory cell that stores the second data,
the memory cells included in the second string include a fifth memory cell that stores complementary data of the first data, a sixth memory cell that stores the first data, a seventh memory cell that stores the second data, and an eighth memory cell that stores complementary data of the second data, and
the program is further configured to execute an exclusive OR process, and to apply, in the exclusive OR process, the first voltage to the select transistors of the first string and the second string, the third voltage to each of the first memory cell, the third memory cell, the fifth memory cell and the seventh memory cell, and the fourth voltage to each of the second memory cell, the fourth memory cell, the sixth memory cell and the eighth memory cell.

20. The storage medium of claim 18, wherein
the memory cells included in the first string include a first memory cell that stores first data, a second memory cell that stores complementary data of the first data, a third memory cell that stores complementary data of second data, and a fourth memory cell that stores the second data,
the memory cells included in the second string include a fifth memory cell that stores complementary data of the first data, a sixth memory cell that stores the first data, a seventh memory cell that stores the second data, and an eighth memory cell that stores complementary data of the second data, and
the program is further configured to execute an exclusive NOR process, and to apply, in the exclusive NOR process, the first voltage to the select transistors of the first string and the second string, the third voltage to each of the first memory cell, the fourth memory cell, the fifth memory cell and the eighth memory cell, and the fourth voltage to each of the second memory cell, the third memory cell, the sixth memory cell and the seventh memory cell.
